(19) United States
(12) Patent Application Publication
(10) Pub. No.: US 2024/0240059 A1
(43) Pub. Date: Jul. 18, 2024

(54) EPOXY RESIN MODIFIER, EPOXY RESIN COMPOSITION CONTAINING SAME, ADHESIVE COMPOSED OF EPOXY RESIN COMPOSITION, AND RESIN CURED PRODUCT OBTAINED BY CURING EPOXY RESIN COMPOSITION

(71) Applicant: OTSUKA CHEMICAL CO., LTD., Osaka-shi, Osaka (JP)

(72) Inventor: Yohei TAKAHASHI, Tokushima-shi (JP)

(73) Assignee: OTSUKA CHEMICAL CO., LTD., Osaka-shi, Osaka (JP)

(21) Appl. No.: 18/563,617

(22) PCT Filed: Jun. 16, 2022
(86) PCT No.: PCT/JP2022/024142

§ 371 Date: Nov. 22, 2023

(30) Foreign Application Priority Data
Jun. 29, 2021 (JP) 2021-107829

(51) Int. Cl. C09J 11/08; C08F 297/02; C09J 163/00

(52) U.S. Cl. CPC C09J 11/08; C08F 297/026; C09J 163/00

(57) ABSTRACT

[Problem] An object of the present invention is to provide an epoxy resin modifier capable of imparting excellent fracture toughness and peel adhesion strength while maintaining high transparency when added into an epoxy resin to form a cured product, an epoxy resin composition containing the epoxy resin modifier, an adhesive and an underfill material composed of the epoxy resin composition, and a cured product obtained by curing the epoxy resin composition.

[Solution] The epoxy resin modifier according to the present invention contains an A-B-A triblock copolymer having an A block that has a structural unit (a-1) represented by the general formula (1) and a structural unit (a-2) derived from a (meth)acrylate having a chain alkyl group, and a B block that has a structural unit (b) derived from a (meth)acrylate having a chain alkyl group or a cyclic alkyl group, an amount of the structural unit (a-1) is 85 mass % or more and less than 100 mass % in 100 mass % of each A block, and an amount of the structural unit (a-2) is more than 0 mass % and 15 mass % or less in 100 mass % of each A block.

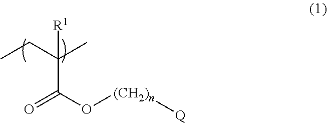

[In the general formula (1), R¹ is a hydrogen atom or a methyl group, 0≤n≤10, and Q is a four-membered to six-membered cyclic ether group or cyclic thioether group.]

### TECHNICAL FIELD

The present invention relates to an epoxy resin modifier, an epoxy resin composition containing the epoxy resin modifier, an adhesive and an underfill material composed of the epoxy resin composition, and a cured resin product obtained by curing the epoxy resin composition.

### BACKGROUND TECHNOLOGY

An epoxy resin is a general term for a thermosetting resin obtained by mixing an epoxy resin having an epoxy group (main agent) with an amine, an acid anhydride or the like (curing agent) and heat-curing the mixture. The epoxy resin also has excellent tensile strength, solvent resistance and electrical properties in addition to high elastic modulus, and thus is being used in automobile structural adhesives, civil engineering and construction paints, sealing materials (potting materials, underfill materials) of electronic materials such as semiconductors, aircraft composite materials, sporting goods composite materials, etc. For example, when a semiconductor circuit is subjected to a heat cycle test, excessive mechanical stress is applied to solder bumps or the like due to the difference in linear expansion coefficient between the circuit board and the semiconductor chip, cracks occur in the solder bumps or the like, and the connection reliability of the semiconductor circuit may be impaired. To solve this problem, the gap between the circuit board and the semiconductor chip is filled with an underfill material made of the epoxy resin.

However, since the epoxy resin has high elastic modulus, the epoxy resin is characteristic of easily generating microcracks in the resin. Therefore, fracture toughness or peel adhesion strength is weak, and improvement thereof is required. Therefore, many attempts for improving the toughness or peel adhesion strength of the epoxy resin have been made.

For example, the Patent Document 1 discloses adding a block copolymer in an epoxy resin to improve toughness, wherein the block copolymer has an A block having a structural unit derived from a (meth)acrylate with a four-membered to six-membered cyclic ether group or cyclic thioether group, and a B block having a structural unit derived from a (meth)acrylate with a chain alkyl group or cyclic alkyl group.

The Patent Document 2 discloses adding core/shell particles in an epoxy resin to improve toughness (impact resistance), wherein the core is mainly composed of polybutadiene or polybutyl acrylate, and the shell is mainly composed of a (meth)acrylate-based polymer.

The Patent Document 3 discloses adding a block copolymer in an epoxy resin to improve toughness and stiffness, wherein the block copolymer includes a polymer block (a) composed of a (meth)acrylic polymer, and a polymer block (b) composed of an acrylic polymer different from that of the polymer block (a).

The Patent Document 4 discloses adding a block copolymer in an epoxy resin to improve fracture toughness and peel adhesion strength, wherein the block copolymer has one or more polymer block A primarily composed of a structural unit derived from an alkyl methacrylate, and one or more polymer block B primarily composed of a structural unit derived from an alkyl acrylate.

### PRIOR ART LITERATURE

### Patent Document

[Patent Document 1] JP 2018-35266 A
[Patent Document 2] JP H9-25393 A
[Patent Document 3] JP 2014-142024 A
[Patent Document 4] JP 2009-101961 A

### SUMMARY OF THE INVENTION

### Problem to be Solved by the Invention

In recent years, the performance of automobile structural adhesives, electronic materials such as semiconductors, aeronautical materials or the like is becoming higher. Therefore, the epoxy resin to be used for these materials is also required to have higher performance, but when the above methods are used to sufficiently improve the toughness or peel adhesion strength, the proportion of the modifier (block copolymer or core/shell particles) contained in the epoxy resin must be increased. However, a large proportion of the modifier weakens tensile strength or solvent resistance which are properties inherent to the epoxy resin, and thus the epoxy resin containing a large proportion of the modifier cannot be applied to the materials that require such properties. Moreover, since the transparency of the resin is also lost, the epoxy resin containing a large proportion of the modifier cannot be applied to the materials that require transparency.

An object of the present invention is to provide an epoxy resin modifier capable of imparting excellent fracture toughness and peel adhesion strength while maintaining high transparency when added into an epoxy resin to form a cured product, an epoxy resin composition containing the epoxy resin modifier, an adhesive composed of the epoxy resin composition, an underfill material composed of the epoxy resin composition, and a cured product obtained by curing the epoxy resin composition.

### Means to Solve the Problem

The present invention that has solved the above problem provides an epoxy resin modifier containing a block copolymer, wherein the block copolymer is an A-B-A triblock copolymer having an A block that has a structural unit (a-1) represented by the general formula (1) and a structural unit (a-2) derived from a (meth)acrylate having a chain alkyl group, and a B block that has a structural unit (b) derived from at least one vinyl monomer selected from the group consisting of a (meth)acrylate having a chain alkyl group and a (meth)acrylate having a cyclic alkyl group, and in each of the A blocks, an amount of the structural unit (a-1) represented by the general formula (1) is 85 mass % or more and less than 100 mass % in 100 mass % of the A block, and an amount of the structural unit (a-2) derived from the (meth)acrylate having the chain alkyl group is more than 0 mass % and 15 mass % or less in 100 mass % of the A block.

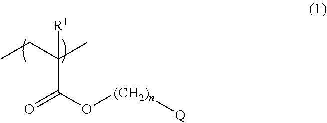

[In the general formula (1), R¹ is a hydrogen atom or a methyl group, 0≤n≤10, and Q is a four-membered to six-membered cyclic ether group or cyclic thioether group.]

The block copolymer contained in the epoxy resin modifier according to the present invention is a A-B-A triblock copolymer having a A block that is a site having high compatibility with an epoxy resin and a B block that is a site having low compatibility with an epoxy resin.

The A block having the high compatibility includes a structural unit (a-1) having high affinity to the epoxy resin and a structural unit (a-2) having lower affinity to the epoxy resin than the structural unit (a-1). It is considered that, if the amount of the structural unit (a-1) having the high affinity to the epoxy resin is 85 mass % or more and less than 100 mass % in 100 mass % of each A block, and the amount of the structural unit (a-2) having the low affinity to the epoxy resin is more than 0 mass % and 15 mass % or less in 100 mass % of each A block, the affinity of the A block with the epoxy resin is neither too high nor too low, and is appropriate. The B block does not substantially include the structural unit (a-1), and thus is considered to have lower affinity to the epoxy resin and lower compatibility with the epoxy resin than the A block.

If the epoxy resin modifier according to the present invention is added in the epoxy resin, a state that the low compatible B block is incompatible with and dispersed in the epoxy resin, i.e. a sea-island structure is formed. It is considered that this island causes cavitation and the surrounding resin relaxes the stress using the generated cavity during crack extension of the epoxy resin, which can disperse the energy of the crack extension. The extent that the energy of the crack extension can be dispersed is affected by the size or morphology of the island.

If the epoxy resin modifier according to the present invention is added in the epoxy resin, the island composed of the B block is in a more uniform nano-sized string-like dispersed state that can disperse the energy of the crack extension most efficiently in the epoxy resin, and thus the obtained cured product of the epoxy resin composition has improved fracture toughness and peel adhesion strength while maintaining high transparency.

The present invention provides an epoxy resin composition containing an epoxy resin, a curing agent, and the epoxy resin modifier. In addition, the present invention provides an adhesive composed of the epoxy resin composition, an underfill material composed of the epoxy resin composition, and a cured resin product obtained by curing the epoxy resin composition.

### Effect of the Invention

According to the present invention, an epoxy resin modifier capable of imparting excellent fracture toughness and peel adhesion strength while maintaining high transparency when added into an epoxy resin to form a cured product can be provided. The cured product of the epoxy resin composition according to the present invention has high transparency and excellent fracture toughness and peel adhesion strength.

### BRIEF DESCRIPTION OF THE DRAWINGS

FIG. 1 is a photograph substituting for a drawing and showing the state of phase separation of a cured product of the epoxy resin composition No. 2;

FIG. 2 is a photograph substituting for a drawing and showing the state of phase separation of a cured product of the epoxy resin composition No. 10; and

FIG. 3 is a photograph substituting for a drawing and showing the state of phase separation of a cured product of the epoxy resin composition No. 6.

### EMBODIMENT FOR CARRYING OUT THE INVENTION

Next, the present invention will be explained based on preferable embodiments, but the present invention is not limited to the following embodiments.

The epoxy resin modifier according to the present invention contains a block copolymer.

### <Block Copolymer>

The block copolymer contained in the epoxy resin modifier according to the present invention is an A-B-A triblock copolymer having an A block that has a structural unit (a-1) represented by the general formula (1) and a structural unit (a-2) derived from a (meth)acrylate having a chain alkyl group, and a B block that has a structural unit (b) derived from at least one vinyl monomer selected from the group consisting of a (meth)acrylate having a chain alkyl group and a (meth)acrylate having a cyclic alkyl group, which will be described later. Further, in each of the A blocks, an amount of the structural unit (a-1) represented by the general formula (1) is 85 mass % or more and less than 100 mass % in 100 mass % of the A block, and an amount of the structural unit (a-2) derived from the (meth)acrylate having the chain alkyl group is more than 0 mass % and 15 mass % or less in 100 mass % of the A block.

The copolymer is preferably a (meth)acrylate based copolymer. The (meth)acrylate based copolymer is a copolymer whose main component (50 mass % or more) is a structural unit derived from a (meth)acrylate, and can further contain a structural unit derived from a vinyl monomer other than the (meth)acrylate. The amount of the structural unit derived from the (meth)acrylate in the copolymer is preferably 80 mass % or more, more preferably 90 mass % or more in 100 mass % of the entire copolymer.

In the present invention, “A block” is interchangeable with “A segment”, and “B block” is interchangeable with “B segment”. In the present invention, “vinyl monomer” refers to a monomer having a radically polymerizable carbon-carbon double bond in the molecule, “structural unit derived from vinyl monomer” refers to a structural unit in which a radically polymerizable carbon-carbon double bond of a vinyl monomer has changed to a carbon-carbon single bond by polymerization, “(meth)acrylic” refers to “either one or both of acrylic and methacrylic”, and “(meth)acrylate” refers to “either one or both of acrylate and methacrylate”. In addition, the (meth)acrylate having the chain alkyl group is a (meth)acrylate having a non-cyclic alkyl group. In the present invention, “(meth)acrylate having chain alkyl group” is interchangeable with “(meth)acrylic acid chain alkyl ester” or “(meth)acrylic acid chain alkyl”, and “(meth)acrylate having cyclic alkyl group” is interchangeable with “(meth)acrylic acid cyclic alkyl ester” or “(meth)acrylic acid cyclic alkyl”.

Various constituent components of the block copolymer will be explained below.

### (A Block)

The A block is a polymer block that has a structural unit (a-1) represented by the general formula (1) and a structural unit (a-2) derived from a (meth)acrylate having a chain alkyl group.

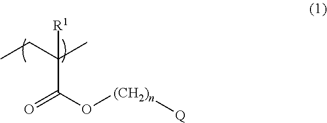

[In the formula (1), R¹ is a hydrogen atom or a methyl group, 0≤n≤10, and Q is a four-membered to six-membered cyclic ether group or cyclic thioether group.]

The n in the formula (1) is preferably an integer ranging from 0 to 10, more preferably an integer ranging from 0 to 5, and even more preferably an integer ranging from 0 to 3.

The four-membered to six-membered cyclic ether group or cyclic thioether group represented by Q is a group having a structure in which at least one of carbon atoms constituting a four-membered to six-membered hydrocarbon ring is replaced with an oxygen atom or a sulfur atom. As long as the group has such structure in which at least one of carbon atoms constituting a four-membered to six-membered hydrocarbon ring is replaced with an oxygen atom or a sulfur atom, the carbon atom constituting the ring may further be replaced with another atom. Specific examples of another atom include a nitrogen atom. In addition, two or more of the carbon atoms constituting the four-membered to six-membered hydrocarbon ring may be replaced with the atom other than the carbon atom. Further, the bond constituting the four-membered to six-membered ring may be a saturated bond or an unsaturated bond. In addition, in the four-membered to six-membered cyclic ether group or cyclic thioether group represented by Q, the hydrogen atom directly bonded to the atom constituting the ring may be replaced with a substituent group. Examples of the substituent group include a hydrocarbon group. It is noted that the group represented by Q has the cyclic ether structure or cyclic thioether structure and is considered to have high compatibility with the epoxy resin, thus an easily ring-opening cyclic acid anhydride group is not preferable.

Specific examples of the four-membered to six-membered cyclic ether group represented by Q include a cyclic ether group in which the carbon atom constituting the four-membered to six-membered ring is replaced with at least one oxygen atom, such as an oxetanyl group (4), a furanyl group (furyl group, 5), a tetrahydrofurfuryl group (6), a pyranyl group (7a, 7b), a dihydropyranyl group (8a, 8b), a tetrahydropyranyl group (9), a dioxolanyl group (10), and a dioxanyl group (11); a cyclic ether group in which the carbon atoms constituting the four-membered to six-membered ring are replaced with an oxygen atom and a nitrogen atom, such as an oxazole group (12), an oxazinyl group (13a to 13h), and a morpholino group (14); a cyclic thioether group in which the carbon atom constituting the four-membered to six-membered ring is replaced with a sulfur atom, such as a thietanyl group (15), and a thienyl group (16); a cyclic thioether group in which the carbon atoms constituting the four-membered to six-membered ring are replaced with a sulfur atom and a nitrogen atom, such as a thiazolyl group (17); and a cyclic ether group (or a cyclic thioether group) in which the carbon atom constituting the four-membered to six-membered ring are replaced with an oxygen atom and a sulfur atom, such as an oxathiolanyl group (18). The chemical formulae of the functional groups are shown below. The number in the parenthesis of the functional group name corresponds to the number of the chemical formula.

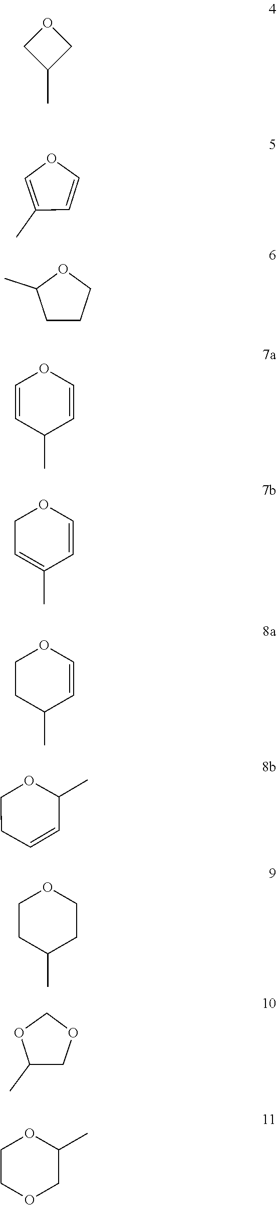

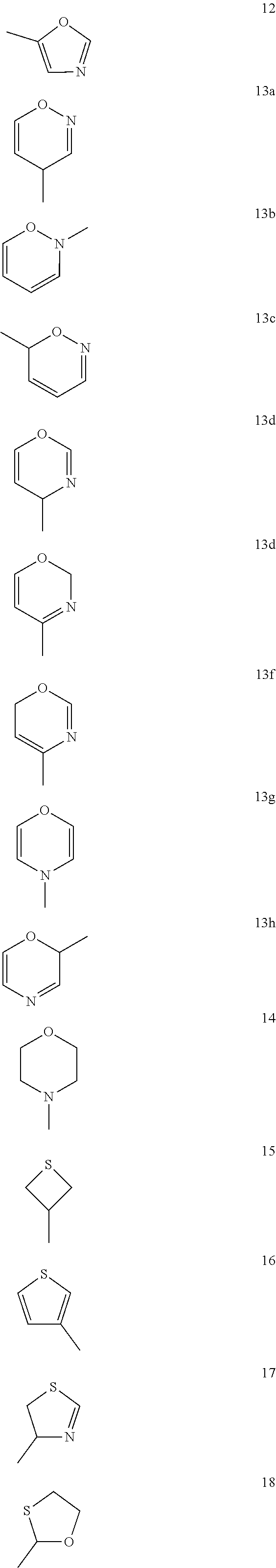

In the chemical formula, the position where the (meth)acrylic acid skeleton bonds to the ring structure of Q is shown as a representative example, but it is not limited to this chemical formula. In other words, the (meth)acrylic acid skeleton can bond to any atom constituting the ring structure of Q.

Q preferably has no unsaturated bond, and for example, an oxetanyl group (4), a tetrahydrofurfuryl group (6), a thietanyl group (15), a tetrahydropyranyl group (9), a dioxolanyl group (10), a dioxanyl group (11), an oxathiolanyl group (18), morpholino group (14) and the like are preferable.

Specific examples of the vinyl monomer forming the structural unit (a-1) represented by the general formula (1) include tetrahydrofurfuryl (meth)acrylate, morpholino (meth)acrylate, morpholinoethyl (meth)acrylate, (3-ethyloxetan-3-yl)methyl (meth)acrylate, (2-methyl-2-ethyl-1,3-dioxolan-4-yl)methyl (meth)acrylate, cyclic trimethylolpropane formal (meth)acrylate, 2-[(2-tetrahydropyranyl)oxy]ethyl (meth)acrylate, and 1,3-dioxane-(meth)acrylate.

The A block may have only one structural unit (a-1) represented by the general formula (1), or may have two or more structural units (a-1) represented by the general formula (1).

The structural unit (a-1) represented by the general formula (1) has the cyclic ether group or cyclic thioether group which has high affinity to the epoxy resin, and thus enhances the compatibility of the A block with the epoxy resin.

The amount of the structural unit (a-1) represented by the general formula (1) in each of the A blocks is 85 mass % or more, preferably 87 mass % or more, more preferably 88 mass % or more, and even more preferably 89 mass % or more, and is less than 100 mass %, preferably 99 mass % or less, more preferably 98 mass % or less, and even more preferably 97 mass % or less in 100 mass % of each A block. If the amount of the structural unit (a-1) falls within the above range, the compatibility of the A block with the epoxy resin is good, and the B block can be dispersed in the epoxy resin on a nanoscale, thus the obtained cured product of the epoxy resin composition exhibits high transparency.

The amount of the structural unit (a-1) in each of the A blocks is an amount in each of the A block at one end and the A block at the other end of the block copolymer.

The A block has a structural unit (a-2) derived from a (meth)acrylate having a chain alkyl group in addition to the above-described structural unit (a-1) represented by the general formula (1). The structural unit (a-2) has lower affinity to the epoxy resin than the structural unit (a-1).

Examples of the chain alkyl group of the (meth)acrylate having the chain alkyl group constituting the structural unit (a-2) include a linear chain alkyl group and a branched chain alkyl group. Examples of the linear chain alkyl group include a methyl group, an ethyl group, a n-propyl group, a n-butyl group, a n-pentyl group, an n-hexyl group, an n-heptyl group, an n-octyl group, an n-nonyl group, and an n-decyl group. Examples of the branched chain alkyl group include an isopropyl group, an isobutyl group, a sec-butyl group, a tert-butyl group, an isopentyl group, a sec-pentyl group, a tert-pentyl group, a neopentyl group, an isohexyl group, a sec-hexyl group, a tert-hexyl group, a 2-ethylhexyl group, an isoheptyl group, an isooctyl group, an isononyl group, and an isodecyl group. Among them, the chain alkyl group having 1 to 10 carbon atoms is preferable, the linear chain alkyl group having 1 to 10 carbon atoms and/or the branched chain alkyl group having 3 to 10 carbon atoms is more preferable, and the branched chain alkyl group having 3 to 10 carbon atoms is even more preferable. If such (meth)acrylate having the chain alkyl group is used, the affinity of the A block to the epoxy resin easily falls in an appropriate range with the good compatibility of the A block with the epoxy resin.

The A block may have only one structural unit (a-2), or may have two or more structural units (a-2).

The amount of the structural unit (a-2) in each of the A blocks is more than 0 mass %, preferably 1 mass % or more, more preferably 2 mass % or more, and even more preferably 3 mass % or more, and is 15 mass % or less, preferably 13 mass % or less, more preferably 12 mass % or less, and even more preferably 11 mass % or less in 100 mass % of each A block. If the amount of the structural unit (a-2) falls within the above range, the affinity of the A block to the epoxy resin is appropriate, and the B block can be dispersed in the epoxy resin in a nano-sized string-like dispersed state, thus the obtained cured product of the epoxy resin composition has excellent fracture toughness and peel adhesion strength.

It is noted that the amount of the structural unit (a-2) in each of the A blocks is an amount in each of the A block at one end and the A block at the other end of the block copolymer.

The A block may consist of the above-described structural units (a-1) and (a-2), or may further include another structural unit (a-3), as long as the appropriate affinity of the A block to the epoxy resin can be maintained.

The other structural unit (a-3) that can be included in the A block is not particularly limited, as long as the other structural unit (a-3) is formed from a vinyl monomer that can be copolymerized with the vinyl monomer forming the structural unit (a-1) represented by the general formula (1), the (meth)acrylate having the chain alkyl group forming the structural unit (a-2), and the vinyl monomer forming the B block described later. Specific examples of the vinyl monomer forming the other structural unit (a-3) of the A block include an aromatic vinyl monomer, a vinyl monomer having a hydroxy group, a vinyl monomer having a carboxy group, a vinyl monomer having a sulfonic acid group, a vinyl monomer having a phosphoric acid group, a vinyl monomer including a tertiary amine, a vinyl monomer including a quaternary ammonium salt group, a vinyl monomer including a heterocycle, a vinylamide, a vinyl monomer including an epoxy group, a vinyl carboxylate, an α-olefin, a diene-based monomer, and a (meth)acrylic monomer.

Examples of the aromatic vinyl monomer include styrene, α-methylstyrene, 4-methylstyrene, 2-methylstyrene, 3-methylstyrene, 4-methoxystyrene, 2-hydroxymethylstyrene, and 1-vinylnaphthalene.

Examples of the vinyl monomer having the hydroxy group include hydroxyalkyl (meth)acrylate.

Examples of the vinyl monomer having the carboxy group include a monomer obtained by reacting the above vinyl monomer having the hydroxy group with an acid anhydride such as maleic anhydride, succinic anhydride or phthalic anhydride, crotonic acid, maleic acid, itaconic acid, and (meth)acrylic acid.

Examples of the vinyl monomer having the sulfonic acid group include vinylsulfonic acid, styrenesulfonic acid, ethyl disulfonic acid (meth)acrylate, methylpropylsulfonate (meth)acrylamide, and ethyl sulfonate (meth)acrylamide.

Examples of the vinyl monomer having the phosphoric acid group include methacryloyloxyethyl phosphate.

Examples of the vinyl monomer having the tertiary amine include N,N-dimethylaminopropyl (meth)acrylamide, N,N-dimethylaminoethyl (meth)acrylamide, 2-(dimethylamino)ethyl (meth)acrylate, and N,N-dimethylaminopropyl (meth)acrylate.

Examples of the vinyl monomer having the quaternary ammonium salt group include N-2-hydroxy-3-acryloyloxypropyl-N,N,N-trimethylammonium chloride, and N-methacryloylaminoethyl-N, N,N-dimethylbenzylammonium chloride.

Examples of the vinyl monomer having the heterocycle include 2-vinylthiophene, N-methyl-2-vinylpyrrole, 1-vinyl-2-pyrrolidone, 2-vinylpyridine, and 4-vinylpyridine.

Examples of the vinylamide include N-vinylformamide, N-vinylacetamide, and N-vinyl-ε-caprolactam.

Examples of the vinyl monomer having the epoxy group include glycidyl (meth)acrylate.

Examples of the vinyl carboxylate include vinyl acetate, vinyl pivalate, and vinyl benzoate. Examples of the α-olefin include 1-hexene, 1-octene, and 1-decene. Examples of the diene-based monomer include butadiene, isoprene, 4-methyl-1,4-hexadiene, and 7-methyl-1,6-octadiene.

Examples of the (meth)acrylic monomer include a (meth)acrylate having a cyclic alkyl group, a (meth)acrylate having a hydroxy group, a (meth)acrylate having an alkoxy group, a (meth)acrylate having a sulfonic acid group, a (meth)acrylate having a tertiary amine, a (meth)acrylate having an epoxy group, a (meth)acrylate having a polyethylene glycol structural unit, a (meth)acrylate having an aromatic ring group, and a (meth)acrylamide.

Examples of the (meth)acrylate having the cyclic alkyl group include cyclohexyl (meth)acrylate, methylcyclohexyl (meth)acrylate, and cyclododecyl (meth)acrylate.

Examples of the (meth)acrylate having the hydroxy group include a hydroxyalkyl (meth)acrylate such as 2-hydroxyethyl (meth)acrylate, 3-hydroxypropyl (meth)acrylate, 2-hydroxypropyl (meth)acrylate, and 4-hydroxybutyl (meth)acrylate.

Examples of the (meth)acrylate having the alkoxy group include methoxyethyl (meth)acrylate, and ethoxyethyl (meth)acrylate.

Examples of the (meth)acrylate having the sulfonic acid group include ethyl disulfonic acid (meth)acrylate.

Examples of the (meth)acrylate having the tertiary amine include 2-(dimethylamino)ethyl (meth)acrylate, and N,N-dimethylaminopropyl (meth)acrylate.

Examples of the (meth)acrylate having the epoxy group include glycidyl (meth)acrylate.

Examples of the (meth)acrylate having the polyethylene glycol structural unit include diethylene glycol mono(meth)acrylate, triethylene glycol mono(meth)acrylate, tetraethylene glycol mono(meth)acrylate, polyethylene glycol mono(meth)acrylate, methoxy diethylene glycol (meth)acrylate, methoxy triethylene glycol (meth)acrylate, methoxy tetraethylene glycol (meth)acrylate, and methoxy polyethylene glycol (meth)acrylate.

Examples of the (meth)acrylate having the aromatic ring group include benzyl (meth)acrylate, phenyl (meth)acrylate, and phenoxyethyl (meth)acrylate.

Examples of the (meth)acrylamide include (meth)acrylamide, N-methyl (meth)acrylamide, N-isopropyl (meth)acrylamide, and N,N-dimethyl (meth)acrylamide.

The vinyl monomer for forming the structural unit (a-3) may be used alone, or two or more of them may be used in combination.

In the case that the A block has the structural unit (a-3), the amount of the structural unit (a-3) in each of the A blocks is preferably 10 mass % or less, more preferably 8 mass % or less, even more preferably 6 mass % or less, and particularly preferably 5 mass % or less in 100 mass % of each A block. It is noted that the lower limit of the amount of the structural unit (a-3) is 0 mass %.

It is noted that the amount of the structural unit (a-3) in each of the A blocks is an amount in each of the A block at one end and the A block at the other end of the block copolymer.

In addition, it is preferable that the A block does not substantially include the structural unit (b) of the B block. In other words, the amount of the structural unit (b) of the B block in the A block is preferably 10 mass % or less, more preferably 8 mass % or less, even more preferably 5 mass % or less, and particularly preferably 2 mass % or less in 100 mass % of each A block. It is noted that the lower limit of the above amount is 0 mass %.

In the case that the A block includes two or more structural units, the various structural units included in the A block may be included in any form of random copolymerization, block copolymerization, or the like in the A block, and are preferably included in the form of random copolymerization from the viewpoint of uniformity. For example, the A block may be formed from a copolymer composed of a block consisting of (a-1) the structural unit and a block consisting of (a-2) the structural unit.

### (B Block)

The B block is a polymer block having the structural unit (b) derived from at least one vinyl monomer selected from the group consisting of the (meth)acrylate having the chain alkyl group, and the (meth)acrylate having the cyclic alkyl group. The B block does not substantially include the above-described structural unit (a-1) derived from the vinyl monomer, and thus is considered to have lower compatibility with the epoxy resin than the A block.

Examples of the (meth)acrylate having the chain alkyl group include dodecyl (meth)acrylate (lauryl (meth)acrylate), tridecyl (meth)acrylate, tetradecyl (meth)acrylate, pentadecyl (meth)acrylate, hexadecyl (meth)acrylate, heptadecyl (meth)acrylate, octadecyl (meth)acrylate (stearyl (meth)acrylate), and nonadecyl (meth)acrylate. Among them, a (meth)acrylate having a chain alkyl group with 11 to 20 carbon atoms is preferable. In addition, the chain alkyl group may be either a linear chain alkyl group or a branched chain alkyl group, and the linear chain alkyl group is preferable.

Examples of the (meth)acrylate having the cyclic alkyl group include cyclohexyl (meth)acrylate, methylcyclohexyl (meth)acrylate, ethylcyclohexyl (meth)acrylate, butylcyclohexyl (meth)acrylate, pentylcyclohexyl (meth)acrylate, and cyclododecyl (meth)acrylate. Among them, a (meth)acrylate having a cyclic alkyl group (particularly a monocyclic alkyl group) with 6 to 15 carbon atoms is preferable.

The vinyl monomer may be used alone, or two or more of them may be used in combination.

As the vinyl monomer for forming the structural unit (b), in particular, the (meth)acrylate having the chain alkyl group is preferably used, the (meth)acrylate having the chain alkyl group with 11 to 20 carbon atoms is more preferably used, the (meth)acrylate having the linear chain alkyl group with 11 to 20 carbon atoms is even more preferably used, and the (meth)acrylate having the linear chain alkyl group with 11 to 15 carbon atoms is particularly preferably used. This is because if the (meth)acrylate having the chain alkyl group with 11 to 20 carbon atoms is used as the vinyl monomer for forming the structural unit (b), the B block becomes flexible, the energy dispersion effect during crack extension is further enhanced, and a cured product of the epoxy resin composition having further enhanced fracture toughness and peel adhesion strength is obtained.

The amount of the structural unit (b) is preferably 80 mass % or more, more preferably 90 mass % or more, even more preferably 95 mass % or more, and particularly preferably 98 mass % or more in 100 mass % of the entire B block. It is noted that the upper limit of the amount of the structural unit (b) is 100 mass %. If the amount of the structural unit (b) falls within the above range, a cured product of the epoxy resin composition having further enhanced fracture toughness and peel adhesion strength is obtained.

The B block may consist of the structural unit (b), or may further include another structural unit, as long as the low compatibility of the B block with the epoxy resin can be maintained. In addition, it is preferable that the B block does not substantially include the structural units (a-1) and (a-2) of the A block. In other words, the amount of each of the structural units (a-1) and (a-2) of the A block in the B block is preferably 10 mass % or less, more preferably 8 mass % or less, even more preferably 5 mass % or less, and particularly preferably 2 mass % or less in 100 mass % of the B block. It is noted that the lower limit of the amount is 0 mass %.

Specific examples of the vinyl monomer for forming the other structural unit of the B block include an aromatic vinyl monomer, a vinyl monomer having a hydroxy group, a vinyl monomer having a carboxy group, a vinyl monomer having a sulfonic acid group, a vinyl monomer having a phosphoric acid group, a vinyl monomer having a tertiary amine, a vinyl monomer having a quaternary ammonium salt group, a vinyl monomer having a heterocycle, a vinylamide, a vinyl monomer having an epoxy group, a vinyl carboxylate, an α-olefin, a diene-based monomer, and a (meth)acrylic monomer.

Examples of the (meth)acrylic monomer include a (meth)acrylate having a hydroxy group, a (meth)acrylate having an alkoxy group, a (meth)acrylate having a sulfonic acid group, a (meth)acrylate having a tertiary amine, a (meth)acrylate having an epoxy group, a (meth)acrylate having a polyethylene glycol structural unit, a (meth)acrylate having an aromatic ring group, and a (meth)acrylamide.

Specific examples of the vinyl monomer include those exemplified as the specific examples of the vinyl monomer for forming the other structural unit (a-3) of the A block.

Each of the vinyl monomers used in the B block may be used alone, or two or more of them may be used in combination.

The amount of the other structural unit of the B block is preferably 20 mass % or less, more preferably 10 mass % or less, and even more preferably 5 mass % or less in 100 mass % of the entire B block. It is noted that the lower limit of the amount of the other structural unit of the B block is 0 mass %.

In the case that the B block includes two or more structural units, the various structural units included in the B block may be included in any form of random copolymerization, block copolymerization, or the like in the B block, and are preferably included in the form of random copolymerization from the viewpoint of uniformity.

### (Block Copolymer)

The block copolymer contained in the epoxy resin modifier according to the present invention is an A-B-A triblock copolymer (A represents the “A block” and B represents the “B block”.). If the block copolymer is the A-B-A triblock copolymer, the B block can be dispersed in the epoxy resin in a more uniform string-like form, thus high peel adhesion strength and fracture toughness can be achieved.

In the A block, the type or amount of each structural unit of the A block at one end may be identical to or different from the type or amount of each structural unit of the A block at the other end.

In the case that, in the A-B-A triblock copolymer, the amount of the structural unit (a-1) in the A block at one end is different from that in the A block at the other end, the block having a higher amount of the structural unit (a-1) is defined as A1 block, and the block having a lower amount of the structural unit (a-1) is defined as A2 block.

The mass ratio (A1 block/A2 block) of the A1 block to the A2 block is not particularly limited, and is preferably 0.8 or more, more preferably 0.85 or more, and is preferably 1.2 or less, more preferably 1.15 or less, and even more preferably 1.1 or less. If the mass ratio (A1 block/A2 block) of the A1 block to the A2 block falls within the above range, islands formed from the B block can be dispersed in the epoxy resin in a more uniform nano-size, thus a cured product of the epoxy resin composition having further enhanced peel adhesion strength and fracture toughness while maintaining transparency can be obtained.

The amount of the A blocks (i.e. the total amount of the A1 block and the A2 block) is preferably 30 mass % or more, more preferably 35 mass % or more, even more preferably 40 mass % or more, and particularly preferably 45 mass % or more, and is preferably 70 mass % or less, more preferably 65 mass % or less, even more preferably 60 mass % or less, and particularly preferably 55 mass % or less in 100 mass % of the entire block copolymer. By adjusting the amount of the A block within the above range, a block copolymer having a desired function can be prepared.

The amount of the B block is preferably 30 mass % or more, more preferably 35 mass % or more, even more preferably 40 mass % or more, and particularly preferably 45 mass % or more, and is preferably 70 mass % or less, more preferably 65 mass % or less, even more preferably 60 mass % or less, and particularly preferably 55 mass % or less in 100 mass % of the entire block copolymer. By adjusting the amount of the B block within the above range, a block copolymer having a desired function can be prepared.

The weight average molecular weight (Mw) of the block copolymer is preferably 10,000 or more, more preferably 20,000 or more, even more preferably 30,000 or more, and particularly preferably 35,000 or more, and is preferably less than 200,000, more preferably less than 100,000, even more preferably less than 80,000, and particularly preferably less than 50,000. If the weight average molecular weight is below the lower limit value, the peel adhesion strength and the fracture toughness are not sufficiently imparted, and if the weight average molecular weight is above the upper limit value, the solubility in the epoxy resin decreases. Thus, if the weight average molecular weight falls within the above range, a cured product of the epoxy resin composition having further enhanced peel adhesion strength and fracture toughness while maintaining transparency can be obtained.

The molecular weight distribution (Mw/Mn) of the block copolymer is particularly 2.0 or less, more particularly 1.6 or less, and even more particularly 1.5 or less. It is noted that the molecular weight distribution (Mw/Mn) in the present invention is a value calculated based on (weight average molecular weight (Mw) of the block copolymer)/(number average molecular weight (Mn) of the block copolymer). A smaller Mw/Mn means a narrower molecular weight distribution, and the copolymer having a small Mw/Mn has a uniform molecular weight. When the value of Mw/Mn is 1.0, the molecular weight distribution is narrowest. If the molecular weight distribution (Mw/Mn) of the block copolymer is more than 2.0, a copolymer having a low molecular weight or a copolymer having a high molecular weight is included. If the molecular weight is low, the peel adhesion strength and the fracture toughness are not sufficiently imparted, and if the molecular weight is high, the solubility in the epoxy resin decreases, so the transparency may not be maintained and the mechanical strength may decrease.

It is noted that the weight average molecular weight and the number average molecular weight in the present invention are measured by gel permeation chromatography (hereinafter referred to as “GPC”).

### (Production Method of Block Copolymer)

The production method of the block copolymer may be a method in which the first A block (e.g. the A1 block) is firstly produced, the monomer of the B block is polymerized with the first A block, and further the monomer of the second A block (e.g. the A2 block) is polymerized with the B block by the polymerization reaction of the vinyl monomers; or a method in which the first A block (e.g. the A1 block), the second A block (e.g. the A2 block) and the B block are produced separately, and then the first A block, the B block and the second A block are coupled.

For example, the block copolymer is obtained by sequentially polymerizing the vinyl monomers constituting the blocks by a radical polymerization method. Specific examples of the production method include a production method comprising: a step of polymerizing the vinyl monomer constituting the first A block (e.g. the A1 block) to synthesize the first A block; a step of polymerizing the vinyl monomer constituting the B block with the synthesized first A block to synthesize the B block; and a step of polymerizing the vinyl monomer constituting the second A block (e.g. the A2 block) with the synthesized B block to synthesize the second A block.

The polymerization method is not particularly limited, but living radical polymerization is preferable. In other words, the block copolymer is preferably polymerized by the living radical polymerization. In the conventional radical polymerization method, not only the initiation reaction and the growth reaction but also the termination reaction and the chain transfer reaction cause deactivation of the growing terminal, and tend to result in a mixture of polymers with various molecular weights and non-uniform compositions. The living radical polymerization method is preferable in the point that the termination reaction or chain transfer reaction hardly occurs and the growing terminal grows without deactivation while maintaining the simplicity and versatility of the conventional radical polymerization method, and thus a polymer having a precisely controlled molecular weight distribution and a uniform composition is easily produced.

According to the manners of stabilizing the polymerization growing terminal, the living radical polymerization methods include: a method of using a compound that can generate a nitroxide radical (nitroxide method (NMP method)); a method of using a metal complex of copper, ruthenium or the like, and using a halogenated compound as a polymerization initiation compound from which the living polymerization is initiated (ATRP method); a method of using a dithiocarboxylic acid ester or a xanthate compound (RAFT method); a method of using an organic tellurium compound (TERP method); a method of using an organic iodine compound (ITP method); a method of using an iodine compound as a polymerization initiation compound, and an organic compound such as a phosphorus compound, a nitrogen compound, an oxygen compound, a hydrocarbon or the like as a catalyst (reversible transfer catalyst polymerization (RTCP method)), and a reversible catalyst mediated polymerization (RCMP method)). Among these methods, the TERP method is preferably used from the viewpoint of diversity of monomers that can be used, molecular weight control in the high molecular region, uniform composition, or coloring.

The living radical polymerization method, particularly the TERP method is preferable because the polymer chain is polymerized while uniformly reacting with the monomer, the composition of all the polymers is nearly uniform, and the probability of forming pseudo-crosslinks increases.

The TERP method is a method of polymerizing a radically polymerizable compound (vinyl monomer) using an organic tellurium compound as a polymerization initiator, and examples thereof include the methods described in WO 2004/14848, WO 2004/14962, WO 2004/072126, and WO 2004/096870.

Specific examples of the polymerization method of the TERP method include the following (a) to (d):
(a) a method of polymerizing a vinyl monomer using an organic tellurium compound represented by the general formula (2);
(b) a method of polymerizing a vinyl monomer using a mixture of the organic tellurium compound represented by the general formula (2) and an azo polymerization initiator;
(c) a method of polymerizing a vinyl monomer using a mixture of the organic tellurium compound represented by the general formula (2) and an organic ditellurium compound represented by the general formula (3); and
(d) a method of polymerizing a vinyl monomer using a mixture of the organic tellurium compound represented by the general formula (2), the azo polymerization initiator, and the organic ditellurium compound represented by the general formula (3).

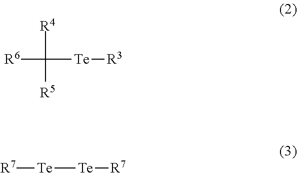

[In the general formula (2), R³ represents an alkyl group having 1 to 8 carbon atoms, an aryl group or an aromatic heterocycle group. R⁴ and R⁵ each independently represent a hydrogen atom or an alkyl group having 1 to 8 carbon atoms. R⁶ represents an alkyl group having 1 to 8 carbon atoms, an aryl group, a substituted aryl group, an aromatic heterocycle group, an alkoxy group, an acyl group, an amide group, an oxycarbonyl group, a cyano group, an allyl group or a propargyl group.]

[In the general formula (3), R⁷ represents an alkyl group having 1 to 8 carbon atoms, an aryl group or an aromatic heterocycle group.]

The group represented by R³ is an alkyl group having 1 to 8 carbon atoms, an aryl group or an aromatic heterocycle group, and specific examples thereof are as follows. Examples of the alkyl group having 1 to 8 carbon atoms include a straight or branched chain alkyl group such as a methyl group, an ethyl group, an n-propyl group, an isopropyl group, an n-butyl group, an isobutyl group, a sec-butyl group, a tert-butyl group, a pentyl group, a hexyl group, a heptyl group, and an octyl group; and a cyclic alkyl group such as a cyclohexyl group. The linear or branched chain alkyl group having 1 to 4 carbon atoms is preferable, a methyl group or an ethyl group is more preferable. Examples of the aryl group include a phenyl group and a naphthyl group. Examples of the aromatic heterocycle group include a pyridyl group, a furyl group and a thienyl group.

The groups represented by R⁴ and R⁵ are each independently a hydrogen atom or an alkyl group having 1 to 8 carbon atoms, and specific examples of each group are as follows. Examples of the alkyl group having 1 to 8 carbon atoms include a straight or branched chain alkyl group such as a methyl group, an ethyl group, an n-propyl group, an isopropyl group, an n-butyl group, an isobutyl group, a sec-butyl group, a tert-butyl group, a pentyl group, a hexyl group, a heptyl group, and an octyl group; and a cyclic alkyl group such as a cyclohexyl group. The linear or branched chain alkyl group having 1 to 4 carbon atoms is preferable, a methyl group or an ethyl group is more preferable.

The group represented by R⁶ is an alkyl group having 1 to 8 carbon atoms, an aryl group, a substituted aryl group, an aromatic heterocycle group, an alkoxy group, an acyl group, an amide group, an oxycarbonyl group, a cyano group, an allyl group or a propargyl group, and specific examples thereof are as follows.

Examples of the alkyl group having 1 to 8 carbon atoms include a straight or branched chain alkyl group such as a methyl group, an ethyl group, an n-propyl group, an isopropyl group, an n-butyl group, an isobutyl group, a sec-butyl group, a tert-butyl group, a pentyl group, a hexyl group, a heptyl group, and an octyl group; and a cyclic alkyl group such as a cyclohexyl group. The linear or branched chain alkyl group having 1 to 4 carbon atoms is preferable, a methyl group or an ethyl group is more preferable.

Examples of the aryl group include a phenyl group and a naphthyl group. The phenyl group is preferable.

Examples of the substituted aryl group include a phenyl group having a substituent group and a naphthyl group having a substituent group. Examples of the substituent group of the aryl group having the substituent group include a halogen atom, a hydroxy group, an alkoxy group, an amino group, a nitro group, a cyano group, a carbonyl-containing group represented by —COR⁶¹ (R⁶¹ is an alkyl group having 1 to 8 carbon atoms, an aryl group, an alkoxy group having 1 to 8 carbon atoms or an aryloxy group), a sulfonyl group, and a trifluoromethyl group. In addition, the substituent group may be one or two.

Examples of the aromatic heterocycle group include a pyridyl group, a furyl group, and a thienyl group.

The alkoxy group is preferably a group in which an alkyl group having 1 to 8 carbon atoms is bonded to an oxygen atom, and examples thereof include a methoxy group, an ethoxy group, a propoxy group, an isopropoxy group, an n-butoxy group, a sec-butoxy group, a tert-butoxy group, a pentyloxy group, a hexyloxy group, a heptyloxy group, and an octyloxy group.

Examples of the acyl group include an acetyl group, a propionyl group, and a benzoyl group.

Examples of the amide group include —CONR⁶²¹R⁶²² (R⁶²¹ and R⁶²² are each independently a hydrogen atom, an alkyl group having 1 to 8 carbon atoms or an aryl group).

The oxycarbonyl group is preferably a group represented by —COOR⁶³ (R⁶³ is a hydrogen atom, an alkyl group having 1 to 8 carbon atoms or an aryl group), and examples thereof include a carboxy group, a methoxycarbonyl group, an ethoxycarbonyl group, a propoxycarbonyl group, an n-butoxycarbonyl group, a sec-butoxycarbonyl group, a tert-butoxycarbonyl group, an n-pentoxycarbonyl group, and a phenoxycarbonyl group. Preferable examples of the oxycarbonyl group include a methoxycarbonyl group, and an ethoxycarbonyl group.

Examples of the allyl group include —CR⁶⁴¹R⁶⁴²—CR⁶⁴³═CR⁶⁴⁴R⁶⁴⁵ (R⁶⁴¹ and R⁶⁴² are each independently a hydrogen atom or an alkyl group having 1 to 8 carbon atoms, R⁶⁴³, R⁶⁴⁴ and R⁶⁴⁵ are each independently a hydrogen atom, an alkyl group having 1 to 8 carbon atoms or an aryl group, and various substituent groups may be connected in a cyclic structure).

Examples of the propargyl group include —CR⁶⁵¹R⁶⁵²—C≡CR⁶⁵³ (R⁶⁵¹ and R⁶⁵² are a hydrogen atom or an alkyl group having 1 to 8 carbon atoms, R⁶⁵³ is a hydrogen atom, an alkyl group having 1 to 8 carbon atoms, an aryl group or a silyl group).

Specific examples of the organic tellurium compound represented by the general formula (2) include (methylteranylmethyl) benzene, (methylteranylmethyl) naphthalene, ethyl=2-methyl-2-methylteranyl-propionate, ethyl=2-methyl-2-n-butylteranyl-propionate, (2-trimethylsiloxyethyl)=2-methyl-2-methylteranyl-propinate, (2-hydroxyethyl)=2-methyl-2-methylteranyl-propinate, (3-trimethylsilylpropargyl)=2-methyl-2-methylteranyl-propinate, and all organic tellurium compounds described in WO 2004/14848, WO 2004/14962, WO 2004/072126 and WO 2004/096870.

In the general formula (3), the group represented by R⁷ is an alkyl group having 1 to 8 carbon atoms, an aryl group or an aromatic heterocycle group, and specific examples thereof are as follows.

Examples of the alkyl group having 1 to 8 carbon atoms include a straight or branched chain alkyl group such as methyl group, ethyl group, n-propyl group, isopropyl group, n-butyl group, isobutyl group, sec-butyl group, tert-butyl group, pentyl group, hexyl group, heptyl group, and octyl group; and a cyclic alkyl group such as cyclohexyl group. The linear or branched chain alkyl group having 1 to 4 carbon atoms is preferable, methyl group or ethyl group is more preferable. Examples of the aryl group include phenyl group and naphthyl group. Examples of the aromatic heterocycle group include pyridyl group, furyl group and thienyl group.

Specific examples of the organic ditellurium compound represented by the general formula (3) include dimethyl ditelluride, diethyl ditelluride, di-n-propyl ditelluride, diisopropyl ditelluride, dicyclopropyl ditelluride, di-n-butyl ditelluride, di-s-butyl ditelluride, di-t-butyl ditelluride, dicyclobutyl ditelluride, diphenyl ditelluride, bis-(p-methoxyphenyl) ditelluride, bis-(p-aminophenyl) ditelluride, bis-(p-nitrophenyl) ditelluride, bis-(p-cyanophenyl) ditelluride, bis-(p-sulfonylphenyl) ditelluride, dinaphthyl ditelluride, and dipyridyl ditelluride.

As the azo polymerization initiator, any azo polymerization initiator that is commonly used in radical polymerization can be used without any particular limitation. Examples of the azo polymerization initiator include 2,2′-azobis(isobutyronitrile) (AIBN), 2,2′-azobis(2-methylbutyronitrile) (AMBN), 2,2′-azobis(2,4-dimethylvaleronitrile) (ADVN), 1,1′-azobis(1-cyclohexanecarbonitrile) (ACHN), dimethyl-2,2′-azobisisobutyrate (MAIB), 4,4′-azobis(4-cyanovaleric acid) (ACVA), 1,1′-azobis(1-acetoxy-1-phenylethane), 2,2′-azobis(2-methylbutylamide), 2,2′-azobis(4-methoxy-2,4-dimethylvaleronitrile) (V-70), 2,2′-azobis(2-methylamidinopropane) dihydrochloride, 2,2′-azobis[2-(2-imidazolin-2-yl)propane], 2,2′-azobis[2-methyl-N-(2-hydroxyethyl)propionamide], 2,2′-azobis(2,4,4-trimethylpentane), 2-cyano-2-propylazoformamide, 2,2′-azobis(N-butyl-2-methylpropionamide), and 2,2′-azobis(N-cyclohexyl-2-methylpropionamide).

In the polymerization methods (a), (b), (c) and (d), the amount of the vinyl monomer may be appropriately adjusted according to the desired physical properties of the copolymer. Generally, the amount of the vinyl monomer preferably ranges from 5 mol to 10000 mol with respect to 1 mol of the organic tellurium compound represented by the general formula (2).

In the polymerization method (b), when the organic tellurium compound represented by the general formula (2) and the azo polymerization initiator are used in combination, generally, the amount of the azo polymerization initiator preferably ranges from 0.01 mol to 10 mol with respect to 1 mol of the organic tellurium compound represented by the general formula (2).

In the polymerization method (c), when the organic tellurium compound represented by the general formula (2) and the organic ditellurium compound represented by the general formula (3) are used in combination, generally, the amount of the organic ditellurium compound represented by the general formula (3) preferably ranges from 0.01 mol to 100 mol with respect to 1 mol of the organic tellurium compound represented by the general formula (2).

In the polymerization method (d), when the organic tellurium compound represented by the general formula (2), the organic ditellurium compound represented by the general formula (3) and the azo polymerization initiator are used in combination, generally, the amount of the azo polymerization initiator preferably ranges from 0.01 mol to 100 mol with respect to 1 mol of the total amount of the organic tellurium compound represented by the general formula (2) and the organic ditellurium compound represented by the general formula (3).

The polymerization reaction can be carried out without a solvent, but may be carried out using an aprotic or protic solvent generally used in radical polymerization and stirring the mixture. Examples of the aprotic solvent that can be used include benzene, toluene, anisole, N, N-dimethylformamide (DMF), dimethylsulfoxide (DMSO), acetone, acetonitrile, 2-butanone (methylethyl ketone), dioxane, hexafluoroisopropanol, propylene glycol monomethylether acetate, chloroform, carbon tetrachloride, tetrahydrofuran (THF), N-methyl-2-pyrrolidone (NMP), ethyl acetate, propylene glycol monomethylether acetate and trifluoromethyl benzene. In addition, examples of the protic solvent include water, methanol, ethanol, isopropanol, n-butanol, ethyl cellosolve, butyl cellosolve, 1-methoxy-2-propanol and diacetone alcohol.

The amount of the solvent may be appropriately adjusted. For example, the amount of the solvent is generally in a range from 0.01 ml to 50 ml, preferably in a range from 0.05 ml to 10 ml, and more preferably in a range from 0.1 ml to 1 ml with respect to 1 g of the vinyl monomer.

The reaction temperature and reaction time may be appropriately adjusted depending on the molecular weight or molecular weight distribution of the obtained copolymer, but the reaction is usually carried out by stirring at a temperature of 0° C. to 150° C. for 1 minute to 100 hours. The TERP method can provide a high yield and a precise molecular weight distribution even at a low polymerization temperature and a short polymerization time.

After completion of the polymerization reaction, the desired copolymer can be separated from the obtained reaction mixture by a conventional separation and purification means.

The growing terminal of the copolymer obtained by the polymerization reaction is in a form of —TeR³ (wherein R³ is the same as above) derived from the tellurium compound, and is deactivated by the operation in air after the completion of the polymerization reaction. However, the tellurium atom may remain. Since the copolymer having the tellurium atom remaining at the terminal is colored or has poor thermal stability, the tellurium atom is preferably removed.

As a method for removing the tellurium atom, a radical reduction method of using tributylstannane, a thiol compound, or the like; an adsorption method of using activated carbon, silica gel, activated alumina, activated bleaching earth, a molecular sieve, a polymeric adsorbent, or the like; a method of adsorbing a metal with an ion exchange resin or the like; a liquid-liquid extraction method or solid-liquid extraction method in which the tellurium atom at the terminal of the copolymer is oxidized and decomposed by adding a peroxide such as a hydrogen peroxide aqueous solution or benzoyl peroxide, or blowing air or oxygen into the system, and the residual tellurium compound is removed by further combining water washing or appropriate solvent; or a purification method in a solution state, such as ultrafiltration that extracts and removes only those with a specific molecular weight or less, can be used. In addition, these methods can also be used in combination.

### <Epoxy Resin Modifier>

The epoxy resin modifier according to the present invention contains the above-described A-B-A triblock copolymer, and is used by being blended with the epoxy resin.

The epoxy resin modifier according to the present invention may consist of the A-B-A triblock copolymer, or may further contain other components. Examples of the other components that can be contained in the epoxy resin modifier according to the present invention include various conventional additives such as an organic solvent, a stabilizer, a plasticizer, a flame retardant, a flame retardant aid, an antioxidant, and an antistatic agent. The organic solvent is not particularly limited, and examples thereof include xylene, toluene, butanol, ethyl acetate, butyl acetate, N,N-dimethylformamide, methylethyl ketone, methylisobutyl ketone, propylene glycol monomethylether acetate, ethylethoxypropionate, and cyclohexanone.

### <Epoxy Resin Composition>

The epoxy resin composition according to the present invention contains an epoxy resin, a curing agent, and the above-described epoxy resin modifier according to the present invention.

As the epoxy resin used in the present invention, any conventionally known epoxy resin can be used. Specific examples thereof include a bisphenol-type epoxy resin, a phenol novolac-type epoxy resin, an ortho-cresol novolac-type epoxy resin, a biphenyl-type epoxy resin, a dicyclopentadiene-type epoxy resin, a diphenylfluorene-type epoxy resin, halogen-, amino- or alkyl-substituted products of the above epoxy resins, a glycidyl ester-type epoxy resin, a naphthalene-type epoxy resin, an aromatic ring aliphatic ring-containing epoxy resin such as a heterocyclic epoxy resin, an isocyanate-modified epoxy resin, a diarylsulfone-type epoxy resin, a hydroquinone-type epoxy resin, a hydantoin-type epoxy resin, and an epoxy resin (polyepoxy compound) including two or more epoxy groups in the molecule such as resorcinol diglycidyl ether, triglycidyl-p-aminophenol, m-aminophenol triglycidyl ether, tetraglycidylmethylene dianiline, (trihydroxyphenyl)methane triglycidyl ether and tetraphenylethane tetraglycidyl ether. The epoxy resin may be used alone, or two or more of them may be used in combination.

The epoxy resin is preferably liquid even at room temperature (25° C.) from the viewpoint of handleability and adjustment of the composition. The epoxy resin that is liquid at room temperature usually has a weight average molecular weight ranging from 300 to 1000, and an epoxy equivalent ranging from 150 g/eq to 600 g/eq, preferably ranging from 150 g/eq to 200 g/eq. In addition, among the epoxy resins, the bisphenol-type epoxy resin is preferably used from the viewpoints of handleability and processability of the curable resin composition, and heat resistance, fracture toughness, peel adhesion strength and the like of the cured resin product. Specific examples of the bisphenol-type epoxy resin include a bisphenol A-type epoxy resin obtained by a reaction between bisphenol A and epichlorohydrin, a bisphenol F-type epoxy resin obtained by a reaction between bisphenol F and epichlorohydrin, a bisphenol S-type epoxy resin obtained by a reaction between bisphenol S and epichlorohydrin, a bisphenol AD-type epoxy resin obtained by a reaction between bisphenol AD and epichlorohydrin, and halogen- or alkyl-substituted products of the above epoxy resins. Among them, the bisphenol A-type epoxy resin is more preferably used, and the bisphenol A-type diglycidyl ether is even more preferably used, from the viewpoints that the curable resin composition has better handleability and processability, and the cured resin product has better heat resistance.

The type of the curing agent used in the present invention is not particularly limited, and any conventionally used curing agent for epoxy resins can be used. Examples of the curing agent include an acid anhydride-based curing agent, an amine-based curing agent, and a phenol-based curing agent. Among them, the acid anhydride-based curing agent and the amine-based curing agent are preferable, the acid anhydride-based curing agent is more preferable. The acid anhydride-based curing agent is a curing agent having one or more carboxylic anhydride group in one molecule, and the epoxy resin composition is cured by a polycondensation reaction between the epoxy group of the epoxy resin or the like and the carboxylic anhydride group. Examples of the acid anhydride-based curing agent include a cyclic aliphatic acid anhydride, an aromatic acid anhydride, and an aliphatic acid anhydride, and specific examples thereof include maleic anhydride, succinic anhydride, phthalic anhydride, 4-methylphthalic acid anhydride, 4-methylcyclohexanedicarboxylic anhydride, trimellitic anhydride, pyromellitic anhydride, and tetrahydrophthalic anhydride. The amine-based curing agent is a curing agent having one or more amine group in one molecule, and the epoxy resin composition is cured by a polycondensation reaction between the epoxy group of the epoxy resin or the like and the amine group. Examples of the amine-based curing agent include a cyclic aliphatic amine, an aromatic amine, and an aliphatic amine, and specific examples thereof include diethylene triamine, triethylene tetramine, methaxylylene diamine, diaminodiphenyl methane, methane phenylene diamine, and diaminodiphenyl sulfone. Examples of the phenol-based curing agent include phenol novolac resin. These curing agents may be used alone, or two or more of them may be used in combination.

The amount of the curing agent is not particularly limited, and is preferably 5 parts by mass or more, more preferably 25 parts by mass or more, even more preferably 50 parts by mass or more, and particularly preferably 70 parts by mass or more, and is preferably 250 parts by mass or less, more preferably 200 parts by mass or less, and even more preferably 150 parts by mass or less, with respect to 100 parts by mass of the epoxy resin. In addition, the curing agent is preferably 0.5 equivalent to 2.5 equivalents, more preferably 0.5 equivalent to 1.5 equivalents, with respect to the epoxy group in the epoxy resin composition. If the amount of the curing agent falls within the above range, the cured product of the epoxy resin composition has enhanced mechanical properties.

The epoxy resin composition according to the present invention preferably further contains a curing accelerator. Specific examples of the curing accelerator include a tertiary amine compound such as benzyldimethylamine, cyclohexyldimethylamine, pyridine, triethanolamine, 2-(dimethylaminomethyl)phenol, dimethylpiperazine, 1,8-diazabicyclo[5,4,0]undec-7-ene (DBU), 1,5-diazabicyclo[4.3.0]non-5-ene (DBN), 1,4-diazabicyclo[2.2.2]octane (DABCO), and 2,4,6-tris(dimethylaminomethyl)phenol; an imidazole compound such as 2-methylimidazole, 2-ethylimidazole, 2-n-heptylimidazole, 2-n-undecylimidazole, 2-phenylimidazole, 2-phenyl-4-methylimidazole, 1-benzyl-2-methylimidazole, 1-benzyl-2-phenylimidazole, 1,2-dimethylimidazole, 2-ethyl-4-methylimidazole, 1-(2-cyanoethyl)-2-methylimidazole, 1-(2-cyanoethyl)-2-n-undecylimidazole, 1-(2-cyanoethyl)-2-phenylimidazole, 1-(2-cyanoethyl)-2-ethyl-4-methylimidazole, 2-phenyl-4-methyl-5-hydroxymethylimidazole, 2-phenyl-4,5-di(hydroxymethyl)imidazole, 1-(2-cyanoethyl)-2-phenyl-4,5-di((2′-cyanoethoxy)methyl)imidazole, 1-(2-cyanoethyl)-2-n-undecyllimidazolium trimellitate, 1-(2-cyanoethyl)-2-phenyllimidazolium trimellitate, 1-(2-cyanoethyl)-2-ethyl-4-methyllimidazolium trimellitate, 2,4-diamino-6-(2′-methylimidazolyl-(1′))ethyl-s-triazine, 2,4-diamino-6-(2′-n-undecylimidazolyl)ethyl-s-triazine, 2,4-diamino-6-(2′-ethyl-4′-methylimidazolyl-(1′))ethyl-s-triazine, isocyanuric acid adduct of 2-methylimidazole, isocyanuric acid adduct of 2-phenylimidazole, and isocyanuric acid adduct of 2,4-diamino-6-(2′-methylimidazolyl-(1′))ethyl-s-triazine; a phosphine compound such as triphenylphosphine or a phosphonium salt such as tetraphenylphosphonium tetraphenylborate; a metal compound such as tin octoate; and a microcapsule-type curing accelerator. These may be used alone, or two or more of them may be used in combination.

The amount of the curing accelerator is not particularly limited, and preferably ranges from 0.1 part by mass to 5 parts by mass, more preferably ranges from 0.2 part by mass to 2 parts by mass, and even more preferably ranges from 0.5 part by mass to 1.5 parts by mass with respect to 100 parts by mass of the epoxy resin. If the amount of the curing accelerator falls within the above range, the cured product of the epoxy resin composition has enhanced mechanical properties.

In the epoxy resin composition according to the present invention, the amount of the epoxy resin modifier according to the present invention in terms of the A-B-A triblock copolymer is preferably 1 part by mass or more, more preferably 3 parts by mass or more, even more preferably 5 parts by mass or more, and is preferably 25 parts by mass or less, more preferably 20 parts by mass or less, even more preferably 15 parts by mass or less, and particularly preferably 10 parts by mass or less, with respect to 100 parts by mass of the total amount of the epoxy resin and the curing agent. If the amount of the epoxy resin modifier is 1 part by mass or more, a cured product of the epoxy resin composition having excellent fracture toughness and peel adhesion strength is obtained. In addition, if the amount of the epoxy resin modifier is 25 parts by mass or less, the functional deterioration of the epoxy resin (tensile strength, solvent resistance, etc.) due to the excessive addition of the epoxy resin modifier can be suppressed while maintaining the high transparency.

In addition to the epoxy resin, the curing agent, the curing accelerator, and the epoxy resin modifier according to the present invention, the epoxy resin composition according to the present invention may further contain other additives where necessary, as long as the additives do not impair the effect of the present invention. Examples of the additives include a reactive diluent such as n-butanol glycidyl ether, butyl glycidyl ether, butylphenyl glycidyl ether, hexyl glycidyl ether, 2-ethylhexyl glycidyl ether, allyl glycidyl ether, tetrahydrofurfuryl glycidyl ether, furfuryl glycidyl ether, trimethoxysilyl glycidyl ether, other higher alcohol-based glycidyl ether, glycidyl methacrylate, polyfunctional 1,4-butanediol·diglycidyl ether, 1,6-hexanediol·diglycidyl ether, trimethylolpropane triglycidyl ether, polyethylene glycol diglycidyl ether, and dimer acid diglycidyl ester; a thixotropic agent such as carbon black e.g. Ketjenblack, silica, fine particle calcium carbonate, and sepiolite; a filler such as calcium carbonate, talc, magnesia, calcium silicate, aluminum hydroxide, calcium hydroxide, magnesium hydroxide, alumina, zircon, graphite, barium sulfate, clay, mica, kaolin, wollastonite, mica, feldspar, syenite, chlorite, bentonite, montmorillonite, barite, cristobalite, dolomite, quartz, diatomaceous earth, aluminum silicate, barium carbonate, magnesium carbonate, zinc carbonate, mineral fiber, textile fiber, glass fiber, aramid pulp, boron fiber, carbon fiber, phosphate, silica e.g. crystalline silica, amorphous silica, fused silica, fumed silica, pyrogenic silica, precipitated silica and pulverized (fine powder) silica, pyroxene, silica sand, cellulose, cement, resin powder e.g. polyethylene, calcium oxide, iron oxide, zinc oxide, titanium oxide, barium oxide, magnesium oxide, titanium dioxide, hollow inorganic beads e.g. hollow ceramic beads and hollow glass beads, hollow organic beads formed of polyester resin or the like, glass beads, metal powder, and bituminous substance; a reaction retarder; an aging inhibitor; an antioxidant; a plasticizer; a tackifier; a flame retardant; an antistatic agent; an UV absorber; a surfactant; a dispersing agent; an deforming agent; a rheology adjusting agent; a polymerization inhibitor; a pigment; a dye; a coupling agent; an ion scavenger; a release agent; a thermosetting resin other than the epoxy resin; and a thermoplastic resin.

The epoxy resin composition according to the present invention preferably contains a reactive diluent. As the reactive diluent, 1,6-hexanediol diglycidyl ether and butylglycidyl ether are preferable. The amount of the reactive diluent in the epoxy resin composition is preferably 0.1 mass % or more, more preferably 1 mass % or more, and is preferably 10 mass % or less, more preferably 7 mass % or less. If the amount of the reactive diluent falls within the above range, the viscosity of the epoxy resin composition can be lowered while maintaining the excellent fracture toughness.

The method for producing the epoxy resin composition according to the present invention is not particularly limited, and any production method that can uniformly mix the epoxy resin, the curing agent, the epoxy resin modifier according to the present invention, if necessary the curing accelerator or other additives. The epoxy resin composition according to the present invention can be produced by adopting, for example, (1) a method in which the epoxy resin is introduced into a reactor, the epoxy resin is heated to a liquid at a suitable temperature when the epoxy resin is a solid, the epoxy resin modifier is added therein and dissolved, the curing agent or curing accelerator is added therein, the mixture is uniformly mixed in a liquid state, and if necessary a defoaming treatment is performed, to produce the epoxy resin composition; (2) a method in which the epoxy resin, the curing agent or curing accelerator, and the epoxy resin modifier are uniformly mixed using a mixer or the like, and then melt kneaded using a hot roll, a twin screw extruder, a kneader or the like, to produce the epoxy resin composition; or (3) a method in which the epoxy resin, the curing agent or curing accelerator, and the epoxy resin modifier are dissolved in a solvent such as methylethyl ketone, acetone or toluene, to produce a varnish-like epoxy resin composition.

### <Adhesive>

The epoxy resin composition according to the present invention can provide excellent peel adhesion strength, and thus is useful as an adhesive. Examples of the application of the adhesive according to the present invention include vehicle structure uses such as automobiles, civil engineering and construction uses, electronic material uses, general office uses, medical uses, and industrial uses.

### <Underfill Material>

In the manufacture of an electronic device such as a semiconductor device, semiconductor chips are mounted by connecting constituent components such as a board and a semiconductor chip, or a semiconductor chip and a semiconductor chip, with solder bumps or the like. In the semiconductor chip mounting, a sealing material (underfill material) is used to fill a gap between the constituent components. The epoxy resin composition according to the present invention can provide excellent peel adhesion strength and fracture toughness, and thus is also useful as such an underfill material. Examples of the application of the underfill material according to the present invention include semiconductor chip mounting. More specifically, the underfill material according to the present invention can be suitably used for filling a gap between a semiconductor chip and a board or a gap between semiconductor chips connected by solder bumps or the like.

The underfill material according to the present invention is preferably a liquid at room temperature (25° C.). The viscosity of the underfill material according to the present invention at room temperature (25° C.) is preferably 500 mPa's or more, more preferably 1500 mPa's or more, and even more preferably 2500 mPa·s or more, and is preferably 6000 mPa's or less, more preferably 4500 mPa·s or less, and even more preferably 3000 mPa·s or less. If the viscosity of the underfill material falls within the above range, the resin easily penetrates between the board and the semiconductor chip quickly without making gaps, and the resin can be prevented from diffusing during the period from penetration to curing. It is noted that the viscosity is measured by the method described later.

### <Cured Resin Product>

The cured resin product according to the present invention is obtained by curing the above-described epoxy resin composition according to the present invention.

In producing the cured resin product using the epoxy resin composition, any of the conventionally adopted curing methods for epoxy resin compositions can be employed. For example, any of a heat curing method, an energy beam curing method (electron beam curing method, ultraviolet curing method, etc.), and a moisture curing method can be employed, and among them, the heat curing method is preferable from the viewpoint of dispersion of the block copolymer.

When the epoxy resin composition according to the present invention is solid at room temperature (25° C.), for example, the cured resin product (cured molded product) can be produced by pulverizing and tabletting the epoxy resin composition, followed by curing and molding the tabletted epoxy resin composition by a conventional molding method such as transfer molding, compression molding, or injection molding.

In addition, when the epoxy resin composition according to the present invention is liquid or varnish-like at room temperature (25° C.), for example, the cured resin product corresponding to various applications or the like can be obtained by subjecting the epoxy resin composition according to the present invention to an appropriate method such as a method of pouring the epoxy resin composition into a mold (molding), a method of pouring the epoxy resin composition into a container (such as potting), a method of applying the epoxy resin composition on a base material (lamination), or a method of impregnating fibers (filaments) or the like with the epoxy resin composition (such as filament winding), followed by heating and curing the epoxy resin composition.

The curing temperature and curing time for curing the epoxy resin composition according to the present invention may vary depending on the type or the like of the epoxy resin or curing agent, and for example, conditions of a curing temperature from 20° ° C. to 250° C. and a curing time from 1 to 24 hours can be adopted.

The light transmittance of the cured resin product according to the present invention is preferably 30% or more, more preferably 35% or more, and even more preferably 40% or more, when the light transmittance of a cured product of an epoxy resin composition not containing the epoxy resin modifier according to the present invention is deemed as 100%. If the light transmittance is 30% or more, the cured resin product has excellent transparency.

The peel adhesion strength (N/25 mm) of the cured resin product according to the present invention is preferably 3.5 or more, more preferably 5.0 or more, and even more preferably 10.0 or more. If the peel adhesion strength (N/25 mm) is 3.5 or more, the cured resin product has excellent peel adhesion.

The fracture toughness (MPa·m^{1/2}) of the cured resin product according to the present invention is preferably 0.7 or more, more preferably 0.8 or more, and even more preferably 0.9 or more. If the fracture toughness (MPa·m^{1/2}) is 0.7 or more, the cured resin product has excellent fracture toughness.

The linear expansion coefficient relative to the peel adhesion strength (linear expansion coefficient α1/peel adhesion strength) of the cured resin product according to the present invention is preferably 0.6 or more, more preferably 0.8 or more, and even more preferably 1 or more, and is preferably 15 or less, more preferably 10 or less, and even more preferably 5 or less. If the linear expansion coefficient relative to the peel adhesion strength falls within the above range, the temperature cycle resistance is enhanced.

It is noted that the light transmittance, peel adhesion strength, fracture toughness, linear expansion coefficient α1, etc. of the cured resin product according to the present invention are measured by the methods described later.

The cured resin product according to the present invention can be used in various applications in which conventional cured products of epoxy resins are used. In addition, the cured resin product according to the present invention has high transparency, and thus can also be used in applications where transparency is required. Further, the cured resin product according to the present invention has high peel adhesion strength and a low linear expansion coefficient relative to the peel adhesion strength, and thus can be used in adhesive applications for automobile structural adhesion or the like or in underfill material applications for semiconductor chip mounting or the like. Furthermore, the cured resin product according to the present invention has excellent fracture toughness, and thus can be applied to aeronautical material and sports applications which are susceptible to shocks.

### Examples

The present invention will be specifically described below based on examples, but the present invention is not limited to these specific examples.

It is noted that abbreviations have the following meanings.
BTEE: ethyl=2-methyl-2-n-butylteranyl-propionate
DBDT: dibutyl ditelluride
AIBN: 2,2′-azobis(isobutyronitrile)
THEMA: tetrahydrofurfuryl methacrylate
IBMA: isobutyl methacrylate
MMA: methyl methacrylate
LMA: dodecyl methacrylate

### [Evaluation Method]

### (Polymerization Rate)

A nuclear magnetic resonance (NMR) measurement device (model: AVANCE 500 (frequency: 500 MHZ) available from Bruker Biospin Ltd.) was used to measure ¹H-NMR (solvent: deuterated chloroform (CDCl₃), internal standard: tetramethylsilan (TMS)). For the obtained NMR spectrum, the integral ratio of the peak of the vinyl group derived from the monomer to the peak of the ester side chain derived from the polymer was obtained to calculate the polymerization rate of the monomer.

### (Weight Average Molecular Weight (Mw) and Molecular Weight Distribution (Mw/Mn))

A high performance liquid chromatograph (model: HLC-8320GPC available from Tosoh Corporation) was used, and the weight average molecular weight (Mw) and the molecular weight distribution (Mw/Mn) were obtained by gel permeation chromatography (GPC). Two columns of TSKgel SuperMultipore HZ-H (Φ 4.6 mm×150 mm) (available from Tosoh Corporation) were used as a column, tetrahydrofuran was used as a mobile phase, and a differential refractive index detector was used as a detector. The measurement conditions were a column temperature of 40° C., a sample concentration of 5 mg/mL, a sample injection volume of 10 μL, and a flow rate of 0.35 mL/min. Polystyrene (molecular weights of U.S. Pat. Nos. 2,890,000, 1,090,000, 706,000, 427,000, 190,000, 96,400, 37,900, 10,200, 2,630, and 440) was used as a standard substance to create a calibration curve, and the weight average molecular weight (Mw) and number average molecular weight (Mn) were measured. The molecular weight distribution (Mw/Mn) was calculated from these measured values.

### (Viscosity of Epoxy Resin Composition)

The viscosity of the epoxy resin composition (before curing) was measured at room temperature (25° C.) using an E-type viscometer (trade name: TVE-22L available from Toki Sangyo Co., Ltd.). The cone rotor adjusted based on the measured viscosity (1°34′×24 when the viscosity is less than 1500 mPa·s, and 3°×R¹⁴ when the viscosity is 1500 mPa's or more) was used, the rotor rotation speed was 5 rpm, and the measurement range was 5.

### (Transparency of Cured Product of Epoxy Resin Composition)

The light transmittance per 6 mm of the cured product obtained by heating and curing the epoxy resin composition at 120° C. for 90 minutes was measured at 600 nm using a spectrophotometer U-3900 (available from Hitachi High-Tech Science Co. Ltd.). The measurement was conducted ten times, and the average value of the ten measurements was adopted as the value of the light transmittance. The light transmittance of each of the cured products of the epoxy resin compositions in Table 3 and Table 5 is an indexed value when the light transmittance of the cured product of the epoxy resin composition No. 13 containing no block copolymer was deemed as 100%. The light transmittance of the cured products of the epoxy resin compositions No. 14 to 15 in Table 4 is an indexed value when the light transmittance of the cured product of the epoxy resin composition No. 16 containing no block copolymer was deemed as 100%. The light transmittance of the cured products of the epoxy resin compositions No. 17 to 18 in Table 4 is an indexed value when the light transmittance of the cured product of the epoxy resin composition No. 19 containing no block copolymer was deemed as 100%. A larger indexed value means more excellent transparency of the cured product of the epoxy resin composition. When the light transmittance was less than 2%, it was evaluated as “white turbid”.

### (Peel Adhesion Strength of Cured Product of Epoxy Resin Composition: N/25 mm)

The peel adhesion strength test was conducted according to JIS K6854-3. Specifically, two aluminum plates (A1050P, 0.5 mm×25 mm×200 mm) were bent to 90° at a position of 150 mm, and the epoxy resin composition was applied to the 150 mm portion to adhere the two aluminum plates in a T shape. A spacer in a thickness of 0.2 mm was sandwiched at the adhesive layer. After the application, the epoxy resin composition was cured by heating at 120° C. for 90 minutes. After returning to room temperature, a T-type peeling test was conducted at a head speed of 100 mm/min using a mechanical tester Autograph AGS-J available from Shimadzu Corporation. The measurement was conducted five times, and the average value of the five measurements was adopted as the value of the peel adhesion strength.

### (Fracture Toughness of Cured Product of Epoxy Resin Composition)

The epoxy resin composition was poured into a mold having a dimensions of 6×12×25 mm and cured by heating at 120° C. for 90 minutes. The fracture toughness test for the obtained cured product was conducted according to ASTM D5045-93 using a mechanical tester Autograph AGS-J available from Shimadzu Corporation. The measurement was conducted ten times, and the average value of the ten measurements was adopted as the value of the fracture toughness. The fracture toughness K1c means resistance to crack progression, and a larger value thereof means higher fracture toughness.

### (Tensile Strength of Cured Product of Epoxy Resin Composition)

The epoxy resin composition was poured into a mold having a size of a tensile dumbbell test piece No. 3, and cured by heating at 120° C. for 90 minutes. The tensile test for the obtained cured product was conducted according to JIS K 6251 using a mechanical tester Autograph AGS-J available from Shimadzu Corporation. The stress at break of the dumbbell test piece was adopted as the tensile strength. The measurement was conducted ten times, and the average value of the ten measurements was adopted as the value of the tensile strength.

### (Linear Expansion Coefficient of Cured Product of Epoxy Resin Composition)

The cured product obtained by heating and curing the epoxy resin composition at 120° C. for 90 minutes was heated from 30° C. to 300° C. at a speed of 10° C./min using a thermomechanical analyzer (available from Hitachi High-Tech Science Co. Ltd.), and the slope of the tangential line of the obtained chart at 50° C. to 80° C. was adopted as the linear expansion coefficient α1 (ppm/° C.). In addition, the linear expansion coefficient relative to the peel adhesion strength was calculated according to the following formula from the linear expansion coefficient α1 and the peel adhesion strength measured in the peel adhesion strength test.

Linear expansion coefficient relative to peel adhesion strength=linear expansion coefficient α1 (ppm/° C.)/peel adhesion strength (N/25 mm)

### (Observation of Dispersion State of Low Compatible Component in Cured Product of Epoxy Resin Composition)

A microtome (ULTROTOME (registered trademark) V available from LKB BROMMA) was used to cut the cured products of the epoxy resin compositions (No. 2, 10 and 6) into a thickness of 60 nm. After Ruthenium (VIII) oxide (0.5% aqueous solution) was used to stain the low compatible component in the cut piece with Ru, a field emission transmission electron microscope (JEM-2100F available from JEOL Ltd.) or a field emission scanning electron microscope (S-4800 available from Hitachi High Technologies Co., Ltd.) was used to observe the dispersion state of the low compatible component, and a field emission transmission electron microscope image (FE-TEM image) or a field emission scanning electron microscope image (FE-SEM image) was obtained.

### <Synthesis of Block Copolymer>

### (Block Copolymer No. 1)

In a reactor of 300 mL equipped with a stirring machine and purged with nitrogen, 24.38 g of THFMA, 0.63 g of IBMA, 0.74 g of BTEE, 0.41 g of DBDT, 0.0825 g of AIBN and 25.03 g of toluene, which had been purged with nitrogen in advance, were added and reacted at a temperature of 60° C. for 18.25 hours to polymerize the A1 block (first polymerization reaction). The polymerization rate was 97.7%.

In the reaction liquid obtained in the first polymerization reaction, 50.00 g of LMA, 0.0826 g of AIBN and 50.01 g of toluene, which had been purged with nitrogen in advance, were added and reacted at a temperature of 60° C. for 29.25 hours to polymerize the B block (second polymerization reaction). The polymerization rate was 97.4%.

In the reaction liquid obtained in the second polymerization reaction, 24.38 g of THFMA, 0.63 g of IBMA, 0.0823 g of AIBN and 25.12 g of toluene, which had been purged with nitrogen in advance, were added and reacted at 60° C. for 40.00 hours to polymerize the A2 block (third polymerization reaction). The polymerization rate was 99.6%. After completion of the reaction, the reaction liquid was diluted with THF (tetrahydrofuran), and poured into methanol while stirring. The precipitated polymer was filtered under pressure and dried to obtain the A-B-A triblock copolymer No. 1. The block copolymer No. 1 had Mw of 46900 and Mw/Mn of 1.27.

### (Block Copolymers No. 2 to 11)

The block copolymers No. 2 to 11 were produced in the same manner as for the block copolymer No. 1, except that the polymerization reaction was carried out under the material amounts and the reaction conditions shown in Table 1. The block copolymers No. 6, 8 and 10 were A-B diblock copolymers obtained without the third polymerization reaction.

Table 1 shows the used material monomers, organic tellurium compounds, organic ditellurium compounds, azo polymerization initiators, solvents, reaction conditions and polymerization rates. Table 2 shows the compositions, Mw and Mw/Mn of the block copolymers. It is noted that the amount of each structural unit in the block copolymers was calculated based on the ratio of the monomers used in the polymerization reaction and the polymerization rate.

TABLE 1

| Block copolymer No. | | | 1 | 2 | 3 | 4 | 5 | 6 |
|---|---|---|---|---|---|---|---|---|
| A1 block | Vinyl monomer (g) | THFMA | 24.38 | 23.77 | 22.52 | 20.02 | 12.52 | 47.51 |
| polymerization | | IBMA | 0.63 | 1.25 | 2.50 | 5.00 | 12.54 | 2.51 |
| step (first | | MMA | — | — | — | — | — | — |
| polymerization | Organic tellurium compound (g) | BTEE | 0.74 | 0.73 | 0.76 | 0.75 | 0.73 | 0.75 |
| reaction) | Organic ditellurium compound (g) | DBDT | 0.41 | 0.40 | 0.42 | 0.40 | 0.39 | 0.41 |
| | Azo polymerization initiator (g) | AIBN | 0.0825 | 0.0822 | 0.0824 | 0.0828 | 0.0821 | 0.0828 |
| | Solvent (g) | Toluene | 25.03 | 25.02 | 25.00 | 25.01 | 25.03 | 50.08 |
| | Reaction temperature (° C.) | | 60 | 60 | 60 | 60 | 60 | 60 |
| | Reaction time (hour) | | 18.25 | 23.50 | 23.50 | 21.33 | 22.00 | 36.00 |
| | Polymerization rate (%) | | 97.7 | 98.8 | 98.0 | 98.4 | 97.0 | 99.4 |
| B block | Vinyl monomer (g) | LMA | 50.00 | 50.04 | 50.01 | 50.02 | 50.02 | 50.02 |
| polymerization | Azo polymerization initiator (g) | AIBN | 0.0826 | 0.0825 | 0.0828 | 0.0823 | 0.0827 | 0.0831 |
| step (second | Solvent (g) | Toluene | 50.01 | 50.10 | 50.08 | 50.03 | 50.04 | 50.06 |
| polymerization | Reaction temperature (° C.) | | 60 | 60 | 60 | 60 | 60 | 60 |
| reaction) | Reaction time (hour) | | 29.25 | 36.00 | 51.33 | 36.00 | 33.50 | 62.50 |
| | Polymerization rate (%) | | 97.4 | 96.8 | 99.1 | 97.2 | 96.7 | 96.6 |
| A2 block | Vinyl monomer (g) | THFMA | 24.38 | 23.75 | 22.50 | 20.00 | 12.50 | |
| polymerization | | IBMA | 0.63 | 1.26 | 2.50 | 5.01 | 12.51 | |
| step (third | | MMA | — | — | — | — | — | |
| polymerization | Azo polymerization initiator (g) | AIBN | 0.0823 | 0.0824 | 0.0822 | 0.0829 | 0.0826 | |
| reaction) | Solvent (g) | Toluene | 25.12 | 25.10 | 25.02 | 25.04 | 25.12 | |

| | | | | | |
|---|---|---|---|---|---|
| Reaction temperature (° C.) | 60 | 60 | 60 | 60 | 60 |
| Reaction time (hour) | 40.00 | 19.25 | 30.00 | 31.67 | 37.75 |
| Polymerization rate (%) | 99.6 | 97.8 | 97.4 | 96.1 | 96.9 |

| Block copolymer No. | | | 7 | 8 | 9 | 10 | 11 |
|---|---|---|---|---|---|---|---|
| A1 block | Vinyl monomer (g) | THFMA | 23.75 | 47.53 | 25.02 | 50.03 | — |
| polymerization | | IBMA | — | — | — | — | 1.25 |
| step (first | | MMA | 1.26 | 2.50 | — | — | 23.76 |
| polymerization | Organic tellurium compound (g) | BTEE | 0.74 | 0.74 | 0.75 | 0.75 | 0.75 |
| reaction) | Organic ditellurium compound (g) | DBDT | 0.43 | 0.42 | 0.38 | 0.42 | 0.39 |
| | Azo polymerization initiator (g) | AIBN | 0.0828 | 0.0822 | 0.0830 | 0.0826 | 0.0826 |
| | Solvent (g) | Toluene | 25.06 | 50.03 | 25.01 | 50.82 | 25.03 |
| | Reaction temperature (° C.) | | 60 | 60 | 60 | 60 | 60 |
| | Reaction time (hour) | | 19.50 | 37.50 | 23.67 | 35.00 | 26.33 |
| | Polymerization rate (%) | | 99.6 | 97.9 | 99.0 | 99.8 | 97.9 |
| B block | Vinyl monomer (g) | LMA | 50.03 | 50.06 | 50.01 | 50.02 | 50.01 |
| polymerization | Azo polymerization initiator (g) | AIBN | 0.0826 | 0.0823 | 0.0828 | 0.0830 | 0.0824 |
| step (second | Solvent (g) | Toluene | 50.14 | 50.11 | 50.08 | 50.00 | 50.32 |
| polymerization | Reaction temperature (° C.) | | 60 | 60 | 60 | 60 | 60 |
| reaction) | Reaction time (hour) | | 26.33 | 42.00 | 48.00 | 32.33 | 38.50 |
| | Polymerization rate (%) | | 97.4 | 98.7 | 97.4 | 96.6 | 98.6 |
| A2 block | Vinyl monomer (g) | THFMA | 23.77 | | 25.00 | | — |
| polymerization | | IBMA | — | | — | | 1.25 |
| step (third | | MMA | 1.25 | | — | | 23.75 |
| polymerization | Azo polymerization initiator (g) | AIBN | 0.0822 | | 0.0826 | | 0.0823 |
| reaction) | Solvent (g) | Toluene | 25.12 | | 25.08 | | 25.32 |

| | | | |
|---|---|---|---|
| Reaction temperature (° C.) | 60 | 60 | 60 |
| Reaction time (hour) | 38.50 | 31.50 | 36.00 |
| Polymerization rate (%) | 98.1 | 96.2 | 96.7 |

TABLE 2

| Block copolymer No. | | 1 | 2 | 3 | 4 | 5 | 6 |
|---|---|---|---|---|---|---|---|
| A1 | Amount of structural unit derived from THFMA (mass %) | 97.5 | 95.0 | 90.0 | 80.0 | 50.0 | 95.0 |
| block | Amount of structural unit derived from IBMA (mass %) | 2.5 | 5.0 | 10.0 | 20.0 | 50.0 | 5.0 |
| | Amount of structural unit derived from MMA (mass %) | — | — | — | — | — | — |
| | Amount of structural unit (a-1) (mass %) | 97.5 | 95.0 | 90.0 | 80.0 | 50.0 | 95.0 |
| | Amount of structural unit (a-2) (mass %) | 2.5 | 5.0 | 10.0 | 20.0 | 50.0 | 5.0 |
| A2 | Amount of structural unit derived from THFMA (mass %) | 92.7 | 89.2 | 88.4 | 75.7 | 46.9 | — |
| block | Amount of structural unit derived from IBMA (mass %) | 2.4 | 4.7 | 9.8 | 19.0 | 46.9 | — |
| | Amount of structural unit derived from MMA (mass %) | — | — | — | — | — | — |
| | Amount of structural unit derived from LMA (mass %) | 4.9 | 6.0 | 1.8 | 5.3 | 6.2 | — |
| | Amount of structural unit (a-1) (mass %) | 92.7 | 89.2 | 88.4 | 75.7 | 46.9 | — |
| | Amount of structural unit (a-2) (mass %) | 7.3 | 10.7 | 11.6 | 24.3 | 53.1 | — |
| Entire A | A1 block/A2 block (mass ratio) | 0.9 | 0.9 | 1.0 | 1.0 | 0.9 | — |
| block | Average amount of structural unit (a-1) (mass %) | 95.0 | 91.9 | 89.2 | 77.9 | 48.4 | 95.0 |
| | Average amount of structural unit (a-2) (mass %) | 5.0 | 8.1 | 10.8 | 22.1 | 51.6 | 5.0 |
| B block | Amount of structural unit derived from LMA (mass %) | 98.9 | 99.4 | 99.0 | 99.2 | 98.5 | 99.4 |
| | Amount of structural unit derived from THFMA (mass %) | 1.1 | 0.6 | 0.9 | 0.6 | 0.8 | 0.6 |
| | Amount of structural unit derived from IBMA (mass %) | 0.0 | 0.0 | 0.1 | 0.2 | 0.8 | 0.0 |
| | Amount of structural unit derived from MMA (mass %) | — | — | — | — | — | — |
| | Amount of structural unit (b) (mass %) | 98.9 | 99.4 | 99.1 | 99.4 | 99.3 | 99.4 |
| Entire block | Amount of A block (mass %) | 50.7 | 51.0 | 49.6 | 50.5 | 50.5 | 50.5 |
| copolymer | Amount of B block (mass %) | 49.3 | 49.0 | 50.4 | 49.5 | 49.5 | 49.5 |
| | Polymer type | T | T | T | T | T | D |
| | Weight average molecular weight (Mw) | 46900 | 45197 | 43168 | 45445 | 47045 | 51848 |
| | Molecular weight distribution (Mw/Mn) | 1.27 | 1.30 | 1.42 | 1.26 | 1.30 | 1.35 |

| Block copolymer No. | | 7 | 8 | 9 | 10 | 11 |
|---|---|---|---|---|---|---|
| A1 | Amount of structural unit derived from THFMA (mass %) | 95.0 | 95.0 | 100.0 | 100.0 | — |
| block | Amount of structural unit derived from IBMA (mass %) | — | — | — | — | 5.0 |
| | Amount of structural unit derived from MMA (mass %) | 5.0 | 5.0 | — | — | 95.0 |
| | Amount of structural unit (a-1) (mass %) | 95.0 | 95.0 | 100.0 | 100.0 | — |
| | Amount of structural unit (a-2) (mass %) | 5.0 | 5.0 | — | — | 100.0 |
| A2 | Amount of structural unit derived from THFMA (mass %) | 90.3 | — | 95.1 | — | — |
| block | Amount of structural unit derived from IBMA (mass %) | — | — | — | — | 4.9 |
| | Amount of structural unit derived from MMA (mass %) | 4.7 | — | — | — | 92.4 |
| | Amount of structural unit derived from LMA (mass %) | 4.9 | — | 4.9 | — | 2.7 |
| | Amount of structural unit (a-1) (mass %) | 90.3 | — | 95.1 | — | — |
| | Amount of structural unit (a-2) (mass %) | 9.6 | — | 4.9 | — | 100.0 |
| Entire A | A1 block/A2 block (mass ratio) | 1.0 | — | 1.0 | — | 1.0 |
| block | Average amount of structural unit (a-1) (mass %) | 92.7 | 95.0 | 97.6 | 100.0 | — |
| | Average amount of structural unit (a-2) (mass %) | 7.3 | 5.0 | 2.4 | — | 100.0 |
| B block | Amount of structural unit derived from LMA (mass %) | 99.8 | 98.0 | 99.5 | 99.8 | 99.0 |
| | Amount of structural unit derived from THFMA (mass %) | 0.2 | 2.0 | 0.5 | 0.2 | — |
| | Amount of structural unit derived from IBMA (mass %) | — | — | — | — | 0.1 |
| | Amount of structural unit derived from MMA (mass %) | 0.0 | 0.1 | — | — | 1.0 |
| | Amount of structural unit (b) (mass %) | 99.8 | 98.1 | 99.5 | 99.8 | 100.0 |
| Entire block | Amount of A block (mass %) | 50.9 | 49.3 | 50.6 | 50.8 | 50.0 |
| copolymer | Amount of B block (mass %) | 49.1 | 50.7 | 49.4 | 49.2 | 50.0 |
| | Polymer type | T | D | T | D | T |
| | Weight average molecular weight (Mw) | 40421 | 39562 | 42206 | 42507 | 41065 |
| | Molecular weight distribution (Mw/Mn) | 1.33 | 1.39 | 1.19 | 1.39 | 1.37 |

*) Polymer type: T (triblock), D (diblock)

### <Production of Epoxy Resin Composition>

### (Epoxy Resin Compositions No. 1 to 3 and 5 to 12)

A bisphenol A-type epoxy resin (trade name: jER (registered trademark) 828, epoxy equivalent: 194 g/eq, weight average molecular weight: 370, available from Mitsubishi Chemical Corporation) in 49.77 mass %, 4-methylcyclohexane-1,2-dicarboxylic anhydride as a curing agent in 45.28 mass % (2.0 equivalents relative to the epoxy resin), 2-ethyl-4-methylimidazole as a curing accelerator in 0.47 mass %, and the above obtained block copolymer as an epoxy resin modifier in mass % described in Table 3 were mixed, and the mixture was stirred and defoamed for 22 minutes with a stirring and defoaming machine (AR-250 available from Shinki Corporation), to obtain epoxy resin compositions No. 1 to 12.

### (Epoxy Resin Composition No. 4)

A bisphenol A-type epoxy resin (trade name: jER (registered trademark) 828, epoxy equivalent: 194 g/eq, weight average molecular weight: 370, available from Mitsubishi Chemical Corporation) in 47.57 mass %, 4-methylcyclohexane-1,2-dicarboxylic anhydride as a curing agent in 43.28 mass % (2.0 equivalents relative to the epoxy resin), 2-ethyl-4-methylimidazole as a curing accelerator in 0.45 mass %, and the above obtained block copolymer as an epoxy resin modifier in mass % described in Table 3 were mixed, and the mixture was stirred and defoamed for 22 minutes with a stirring and defoaming machine (AR-250 available from Shinki Corporation), to obtain an epoxy resin composition No. 4.

### (Epoxy Resin Composition No. 13)

A bisphenol A-type epoxy resin (trade name: jER (registered trademark) 828, epoxy equivalent: 194 g/eq, weight average molecular weight: 370, available from Mitsubishi Chemical Corporation) in 52.23 mass %, 4-methylcyclohexane-1,2-dicarboxylic anhydride as a curing agent in 47.27 mass % (2.1 equivalents relative to the epoxy resin), and 2-ethyl-4-methylimidazole as a curing accelerator in 0.49 mass % were mixed, and the mixture was stirred and defoamed for 22 minutes with a stirring and defoaming machine (AR-250 available from Shinki Corporation), to obtain an epoxy resin composition No. 13.

### (Epoxy Resin Compositions No. 14 to 15)

A bisphenol F-type epoxy resin (trade name: jER (registered trademark) 807, epoxy equivalent: 168 g/eq, weight average molecular weight: 336, available from Mitsubishi Chemical Corporation) in 47.48 mass %, 4-methylcyclohexane-1,2-dicarboxylic anhydride as a curing agent in 47.57 mass % (2.0 equivalents relative to the epoxy resin), 2-ethyl-4-methylimidazole as a curing accelerator in 0.48 mass %, and the above obtained block copolymer No. 2 or No. 4 as an epoxy resin modifier in mass % described in Table 4 were mixed, and the mixture was stirred and defoamed for 22 minutes with a stirring and defoaming machine (AR-250 available from Shinki Corporation), to obtain epoxy resin compositions No. 14 to 15.

### (Epoxy Resin Composition No. 16)

A bisphenol F-type epoxy resin (trade name: jER (registered trademark) 807, epoxy equivalent: 168 g/eq, weight average molecular weight: 336, available from Mitsubishi Chemical Corporation) in 49.70 mass %, 4-methylcyclohexane-1,2-dicarboxylic anhydride as a curing agent in 49.80 mass % (2.0 equivalents relative to the epoxy resin), and 2-ethyl-4-methylimidazole as a curing accelerator in 0.50 mass % were mixed, and the mixture was stirred and defoamed for 22 minutes with a stirring and defoaming machine (AR-250 available from Shinki Corporation), to obtain an epoxy resin composition No. 16.

### (Epoxy Resin Compositions No. 17 to 18)

A bisphenol A-type epoxy resin (trade name: jER (registered trademark) 828, epoxy equivalent: 194 g/eq, weight average molecular weight: 370, available from Mitsubishi Chemical Corporation) in 75.65 mass %, diaminodiphenylmethane as a curing agent in 19.87 mass % (1.0 equivalent relative to the epoxy resin), and the above obtained block copolymer No. 2 or No. 5 as an epoxy resin modifier in mass % described in Table 4 were mixed, and the mixture was stirred and defoamed for 22 minutes with a stirring and defoaming machine (AR-250 available from Shinki Corporation), to obtain epoxy resin compositions No. 17 to 18.

### (Epoxy Resin Composition No. 19)

A bisphenol A-type epoxy resin (trade name: jER (registered trademark) 828, epoxy equivalent: 194 g/eq, weight average molecular weight: 370, available from Mitsubishi Chemical Corporation) in 79.2 mass %, and diaminodiphenylmethane as a curing agent in 20.8 mass % (1.0 equivalent relative to the epoxy resin) were mixed, and the mixture was stirred and defoamed for 22 minutes with a stirring and defoaming machine (AR-250 available from Shinki Corporation), to obtain an epoxy resin composition No. 19.

### (Epoxy Resin Composition No. 20)

A bisphenol A-type epoxy resin (trade name: jER (registered trademark) 828, epoxy equivalent: 194 g/eq, weight average molecular weight: 370, available from Mitsubishi Chemical Corporation) in 47.51 mass %, 4-methylcyclohexane-1,2-dicarboxylic anhydride as a curing agent in 43.22 mass % (2.0 equivalents relative to the epoxy resin), 2-ethyl-4-methylimidazole as a curing accelerator in 0.45 mass %, the above obtained block copolymer as an epoxy resin modifier in mass % described in Table 5, and a reactive diluent were mixed, and the mixture was stirred and defoamed for 22 minutes with a stirring and defoaming machine (AR-250 available from Shinki Corporation), to obtain an epoxy resin composition No. 20.

### (Epoxy Resin Composition No. 21)

A bisphenol A-type epoxy resin (trade name: jER (registered trademark) 828, epoxy equivalent: 194 g/eq, weight average molecular weight: 370, available from Mitsubishi Chemical Corporation) in 48.36 mass %, 4-methylcyclohexane-1,2-dicarboxylic anhydride as a curing agent in 44.00 mass % (2.0 equivalents relative to the epoxy resin), 2-ethyl-4-methylimidazole as a curing accelerator in 0.46 mass %, the above obtained block copolymer as an epoxy resin modifier in mass % described in Table 5, and a reactive diluent were mixed, and the mixture was stirred and defoamed for 22 minutes with a stirring and defoaming machine (AR-250 available from Shinki Corporation), to obtain an epoxy resin composition No. 21.

The viscosity of the epoxy resin compositions, and the evaluation results of the cured products obtained by curing the epoxy resin compositions are shown in Tables 3 to 5. In addition, the cured product of the epoxy resin composition No. 2 had tensile strength of 36.02 MPa, the cured product of the epoxy resin composition No. 8 had tensile strength of 36.78 MPa, and the cured product of the epoxy resin composition No. 13 had tensile strength of 36.99 MPa.

TABLE 3

| Epoxy resin composition No. | | | 1 | 2 | 3 | 4 | 5 | 6 | 7 |
|---|---|---|---|---|---|---|---|---|---|
| Epoxy resin | | | BisA | BisA | BisA | BisA | BisA | BisA | BisA |
| Curing agent | | | Acid | Acid | Acid | Acid | Acid | Acid | Acid |
| | | | anhydride | anhydride | anhydride | anhydride | anhydride | anhydride | anhydride |
| Block | Block copolymer No. | | 1 | 2 | 3 | 2 | 4 | 5 | 6 |
| copolymer | A1 | Amount of structural | 97.5 | 95.0 | 90.0 | 95.0 | 80.0 | 50.0 | 95.0 |
| | block | unit (a-1) (mass %) | | | | | | | |
| | | Amount of structural | 2.5 | 5.0 | 10.0 | 5.0 | 20.0 | 50.0 | 5.0 |
| | | unit (a-2) (mass %) | | | | | | | |
| | A2 | Amount of structural | 92.7 | 89.2 | 88.4 | 89.2 | 75.7 | 46.9 | — |
| | block | unit (a-1) (mass %) | | | | | | | |
| | | Amount of structural | 7.3 | 10.7 | 11.6 | 10.7 | 24.3 | 53.1 | — |
| | | unit (a-2) (mass %) | | | | | | | |
| | B block | Amount of structural | 98.9 | 99.4 | 99.1 | 99.4 | 99.4 | 99.3 | 99.4 |
| | | unit (b) (mass %) | | | | | | | |
| | Polymer type | | T | T | T | T | T | T | D |
| | Mass % in epoxy resin | | 4.48 | 4.48 | 4.48 | 8.69 | 4.48 | 4.48 | 4.48 |
| | composition | | | | | | | | |
| Epoxy resin | Viscosity (mPa · s) | | 2896 | 2732 | 2889 | 5696 | 2497 | 2619 | 3110 |
| composition | | | | | | | | | |
| (before curing) | | | | | | | | | |
| Cured product of | Light transmittance (%) | | 43.17 | 35.59 | 58.64 | 35.48 | 0.48 | 0.38 | 67.43 |
| epoxy resin | Transparency | | Trans- | Trans- | Trans- | Trans- | White | White | Trans- |
| composition | | | parent | parent | parent | parent | Turbid | Turbid | parent |

| | | | | | | | |
|---|---|---|---|---|---|---|---|
| Peel adhesion strength | 13.98 | 20.02 | 7.05 | 20.24 | 5.81 | 4.02 | 5.95 |
| (N/25 mm) | | | | | | | |
| Fracture toughness K1c | 0.95 | 1.00 | 0.89 | 1.17 | 0.70 | 0.60 | 0.75 |
| (MPa · m^{1/2}) | | | | | | | |
| Linear expansion coefficient | 4.67 | 3.05 | 7.45 | 3.27 | 10.46 | 12.00 | 11.63 |
| relative to peel adhesion | | | | | | | |
| strength | | | | | | | |

| Epoxy resin composition No. | | | 8 | 9 | 10 | 11 | 12 | 13 |
|---|---|---|---|---|---|---|---|---|
| Epoxy resin | | | BisA | BisA | BisA | BisA | BisA | BisA |
| Curing agent | | | Acid | Acid | Acid | Acid | Acid | Acid |
| | | | anhydride | anhydride | anhydride | anhydride | anhydride | anhydride |
| Block | Block copolymer No. | | 7 | 8 | 9 | 10 | 11 | — |
| copolymer | A1 | Amount of structural | 95.0 | 95.0 | 100.0 | 100.0 | — | — |
| | block | unit (a-1) (mass %) | | | | | | |
| | | Amount of structural | 5.0 | 5.0 | — | — | 100.0 | — |
| | | unit (a-2) (mass %) | | | | | | |
| | A2 | Amount of structural | 90.3 | — | 95.1 | — | — | — |
| | block | unit (a-1) (mass %) | | | | | | |
| | | Amount of structural | 9.6 | — | 4.9 | — | 100.0 | — |
| | | unit (a-2) (mass %) | | | | | | |
| | B block | Amount of structural | 99.8 | 98.1 | 99.5 | 98.8 | 100.0 | — |
| | | unit (b) (mass %) | | | | | | |
| | Polymer type | | T | D | T | D | T | — |
| | Mass % in epoxy resin | | 4.48 | 4.48 | 4.48 | 4.48 | 4.48 | 0 |
| | composition | | | | | | | |
| Epoxy resin | Viscosity (mPa · s) | | 2753 | 3276 | 2263 | 2622 | 2753 | 1063 |
| composition | | | | | | | | |
| (before curing) | | | | | | | | |
| Cured product of | Light transmittance (%) | | 65.98 | 49.95 | 48.33 | 51.00 | 0.51 | 100 |
| epoxy resin | Transparency | | Trans- | Trans- | Trans- | Trans- | White | Trans- |
| composition | | | parent | parent | parent | parent | Turbid | parent |

| | | | | | | |
|---|---|---|---|---|---|---|
| Peel adhesion strength | 12.69 | 6.74 | 4.75 | 6.00 | 5.41 | 2.77 |
| (N/25 mm) | | | | | | |
| Fracture toughness K1c | 0.90 | 0.77 | 0.93 | 0.78 | 0.62 | 0.60 |
| (MPa · m^{1/2}) | | | | | | |
| Linear expansion coefficient | 4.14 | 9.91 | 13.22 | 10.32 | 11.60 | 19.36 |
| relative to peel adhesion | | | | | | |
| strength | | | | | | |

*) Epoxy resin: BisA (bisphenol A-type), BisF (bisphenol F-type)
Polymer type: T (triblock), D (diblock)

TABLE 4

| Epoxy resin composition No. | | | 14 | 15 | 16 | 17 | 18 | 19 |
|---|---|---|---|---|---|---|---|---|
| Epoxy resin | | | BisF | BisF | BisF | BisA | BisA | BisA |
| Curing agent | | | Acid | Acid | Acid | Amine | Amine | Amine |
| | | | anhydride | anhydride | anhydride | | | |
| Block | Block copolymer No. | | 2 | 4 | — | 2 | 5 | — |
| copolymer | A1 block | Amount of structural unit (a-1) | 95.0 | 80.0 | — | 95.0 | 50.0 | — |
| | | (mass %) | | | | | | |
| | | Amount of structural unit (a-2) | 5.0 | 20.0 | — | 5.0 | 50.0 | — |
| | | (mass %) | | | | | | |
| | A2 block | Amount of structural unit (a-1) | 89.2 | 75.7 | — | 89.2 | 46.9 | — |
| | | (mass %) | | | | | | |
| | | Amount of structural unit (a-2) | 10.7 | 24.3 | — | 10.7 | 53.1 | — |
| | | (mass %) | | | | | | |
| | B block | Amount of structural unit (b) | 99.4 | 99.4 | — | 99.4 | 99.3 | — |
| | | (mass %) | | | | | | |
| | Polymer type | | T | T | — | T | T | — |
| | Mass % in epoxy resin composition | | 4.48 | 4.48 | 0 | 4.48 | 4.48 | 0 |
| Epoxy resin | Viscosity (mPa · s) | | 948 | 950 | 499 | Not | Not | Not |
| composition | | | | | | measured | measured | measured |
| (before curing) | | | | | | | | |
| Cured product | Light transmittance (%) | | 36.64 | 1.07 | 100 | 67.76 | 0.29 | 100 |
| of epoxy resin | Transparency | | Trans- | White | Trans- | Trans- | White | Trans- |
| composition | | | parent | Turbid | parent | parent | Turbid | parent |

| | | | | | | |
|---|---|---|---|---|---|---|
| Peel adhesion strength (N/25 mm) | 11.20 | 4.59 | 3.16 | 3.82 | 2.98 | 3.28 |
| Fracture toughness K1c (MPa · m^{1/2}) | 0.94 | 0.81 | 0.50 | 0.83 | 0.81 | 0.74 |

*) Epoxy resin: BisA (bisphenol A-type), BisF (bisphenol F-type)
Polymer type: T (triblock), D (diblock)

TABLE 5

| Epoxy resin composition No. | | | 20 | 21 |
|---|---|---|---|---|
| Epoxy resin | | | BisA | BisA |
| Curing agent | | | Acid | Acid |
| | | | anhydride | anhydride |
| Block copolymer | Block copolymer No. | | 2 | 2 |
| | A1 block | Amount of structural unit (a-1) (mass %) | 95.0 | 95.0 |
| | | Amount of structural unit (a-2) (mass %) | 5.0 | 5.0 |
| | A2 block | Amount of structural unit (a-1) (mass %) | 89.2 | 89.2 |
| | | Amount of structural unit (a-2) (mass %) | 10.7 | 10.7 |
| | B block | Amount of structural unit (b) (mass %) | 99.4 | 99.4 |
| | Polymer type | | T | T |
| | Mass % in epoxy resin | | 4.28 | 4.35 |
| | composition | | 4.54 | — |
| Reactive diluent | 1,6-Hexanediol diglycidyl ether (mass % in epoxy resin | | | |
| | composition) | | | |
| | Butyl glycidyl ether (mass % in epoxy resin composition) | | — | 2.83 |
| Epoxy resin | Viscosity (mPa · s) | | 1997 | 1935 |
| composition | | | | |
| (before curing) | | | | |

| | | | |
|---|---|---|---|
| Cured product of | Light transmittance (%) | 60.30 | 49.65 |
| epoxy resin | Transparency | Transparent | Transparent |
| composition | Peel adhesion strength (N/25 mm) | 9.20 | 7.79 |
| | Fracture toughness K1c (MPa · m^{1/2}) | 1.04 | 0.96 |
| | Linear expansion coefficient relative to peel adhesion | 5.28 | 6.50 |
| | strength | | |

*) Epoxy resin: BisA (bisphenol A-type), BisF (bisphenol F-type)
Polymer type: T (triblock), D (diblock)

It is apparent from the results shown in Tables 3 to 5 that even if the epoxy resin modifier according to the present invention is added in a small amount of less than 10 parts by mass with respect to 100 parts by mass of the epoxy resin and curing agent, the obtained cured product of the epoxy resin composition has excellent fracture toughness and peel adhesion strength while showing high transparency. In addition, since the fracture toughness and the peel adhesion strength can be greatly enhanced with a small amount of the epoxy resin modifier according to the present invention, it is possible to suppress deterioration in functions such as the tensile strength of the epoxy resin due to the addition of a large amount of the epoxy resin modifier.

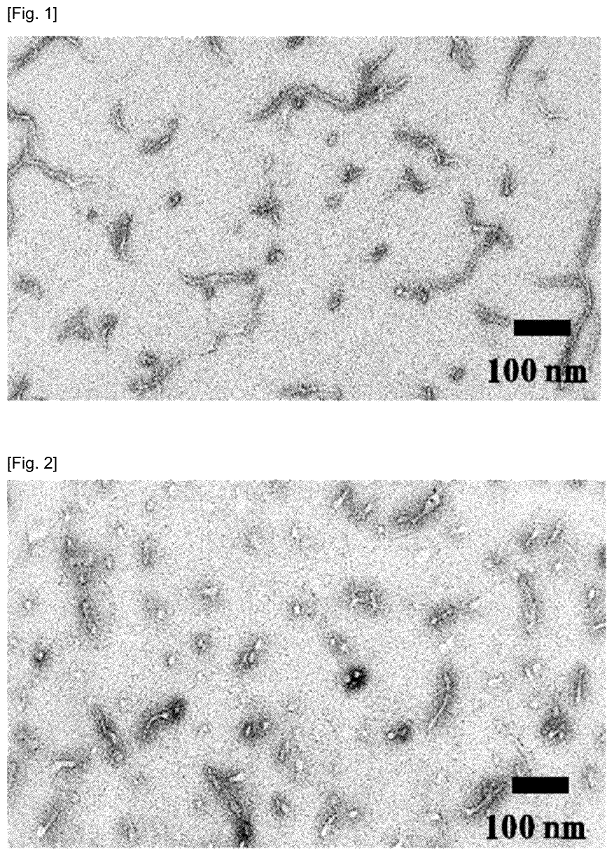

In addition, the results of the dispersion state of the low compatible component in the cured products of the epoxy resin compositions (No. 2, 10 and 6) observed with the electron microscope are shown in FIGS. 1 to 3.

FIG. 1 shows the field emission transmission electron microscope image (FE-TEM image) (black portions are the low compatible component) of the cured product of the epoxy resin composition No. 2. As shown in FIG. 1, in the cured product of the epoxy resin composition No. 2, the low compatible component is dispersed in a form of strings with a width (diameter) of about 10 nm and a length of about 100 nm to 500 nm. It is considered that cavitation easily occurs in the cured product during crack extension since the width is as small as about 10 nm, and stress relaxation is possible in a large area since the volume is large.

FIG. 2 shows the FE-TEM image (black portions are the low compatible component) of the cured product of the epoxy resin composition No. 10. As shown in FIG. 2, in the cured product of the epoxy resin composition No. 10, a part of the low compatible component is string-like, but most of the low compatible component is dispersed in a form of spheres with a diameter of about 10 nm. Therefore, it is considered that the area where the stress can be relaxed is small.

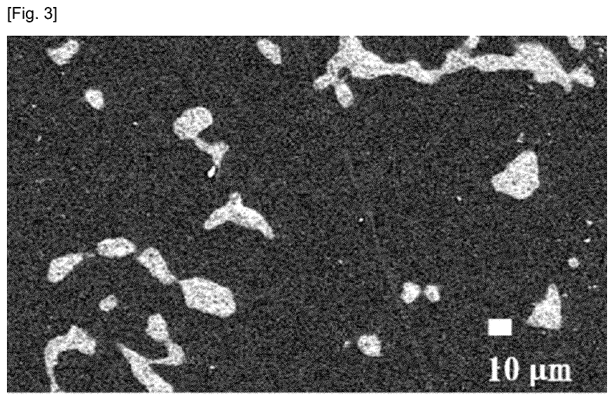

FIG. 3 shows the field emission scanning electron microscope image (FE-SEM image) (white portions are the low compatible component) of the cured product of the epoxy resin composition No. 6. As shown in FIG. 3, in the cured product of the epoxy resin composition No. 6, the low compatible component is dispersed in a macroscopic size in the epoxy resin matrix. Therefore, it is considered that cavitation hardly occurs in the cured product during crack extension.

### INDUSTRIAL APPLICABILITY

The epoxy resin modifier according to the present invention is used by being added in the epoxy resin. If the epoxy resin modifier according to the present invention is added in the epoxy resin, the fracture toughness and peel adhesion strength of the epoxy resin can be enhanced while maintaining the high transparency of the epoxy resin. The epoxy resin composition containing the epoxy resin modifier according to the present invention can be used in various applications in which conventional epoxy resins are used. In addition, the epoxy resin composition has high transparency, and thus can also be used in applications where transparency is required. Further, the epoxy resin composition has high peel adhesion strength, and thus can be used in adhesive applications for automobile structural adhesion or the like or in underfill material applications for semiconductor chip mounting or the like. Furthermore, the epoxy resin composition has excellent fracture toughness, and thus can be applied to aeronautical material and sports applications which are susceptible to shocks.

The preferable embodiment 1 according to the present invention is an epoxy resin modifier containing a block copolymer, wherein the block copolymer is an A-B-A triblock copolymer having an A block that has a structural unit (a-1) represented by the general formula (1) and a structural unit (a-2) derived from a (meth)acrylate having a chain alkyl group, and a B block that has a structural unit (b) derived from at least one vinyl monomer selected from the group consisting of a (meth)acrylate having a chain alkyl group and a (meth)acrylate having a cyclic alkyl group, and in each of the A blocks, an amount of the structural unit (a-1) represented by the general formula (1) is 85 mass % or more and less than 100 mass % in 100 mass % of the A block, and an amount of the structural unit (a-2) derived from the (meth)acrylate having the chain alkyl group is more than 0 mass % and 15 mass % or less in 100 mass % of the A block.

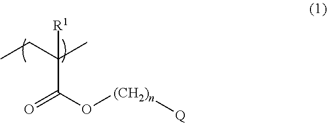

[In the general formula (1), R¹ is a hydrogen atom or a methyl group, 0≤n≤10, and Q is a four-membered to six-membered cyclic ether group or cyclic thioether group.]

The preferable embodiment 2 according to the present invention is the epoxy resin modifier according to the embodiment 1, wherein the structural unit (a-2) of the A block is a structural unit derived from a (meth)acrylate having a branched chain alkyl group.

The preferable embodiment 3 according to the present invention is the epoxy resin modifier according to the embodiment 1 or 2, wherein the structural unit (a-1) of the A block is a structural unit derived from at least one member selected from the group consisting of tetrahydrofurfuryl (meth)acrylate, morpholino (meth)acrylate, morpholinoethyl (meth)acrylate, (3-ethyloxetan-3-yl)methyl (meth)acrylate, (2-methyl-2-ethyl-1,3-dioxolan-4-yl)methyl (meth)acrylate, cyclic trimethylolpropane formal (meth)acrylate, 2-[(2-tetrahydropyranyl)oxy]ethyl (meth)acrylate, and 1,3-dioxane-(meth)acrylate.

The preferable embodiment 4 according to the present invention is the epoxy resin modifier according to any one of the embodiments 1 to 3, wherein when the A block having a high amount of the structural unit (a-1) is referred to as A1 block and the A block having a low amount of the structural unit (a-1) is referred to as A2 block among the two A blocks constituting the block copolymer, a mass ratio (A1 block/A2 block) of the A1 block to the A2 block ranges from 0.8 to 1.2.

The preferable embodiment 5 according to the present invention is the epoxy resin modifier according to any one of the embodiments 1 to 4, wherein an amount of the A block ranges from 30 mass % to 70 mass % in 100 mass % of the entire block copolymer.

The preferable embodiment 6 according to the present invention is the epoxy resin modifier according to any one of the embodiments 1 to 5, wherein the structural unit (b) of the B block is a structural unit derived from a (meth)acrylate having a chain alkyl group with 11 to 20 carbon atoms.

The preferable embodiment 7 according to the present invention is the epoxy resin modifier according to any one of the embodiments 1 to 6, wherein an amount of the structural unit (b) of the B block is 80 mass % or more and 100 mass % or less in 100 mass % of the B block.

The preferable embodiment 8 according to the present invention is the epoxy resin modifier according to any one of the embodiments 1 to 7, wherein an amount of the B block ranges from 30 mass % to 70 mass % in 100 mass % of the entire block copolymer.

The preferable embodiment 9 according to the present invention is the epoxy resin modifier according to any one of the embodiments 1 to 8, wherein the block copolymer has a weight average molecular weight (Mw) of 10,000 or more and less than 200,000.

The preferable embodiment 10 according to the present invention is the epoxy resin modifier according to any one of the embodiments 1 to 9, wherein the block copolymer has a molecular weight distribution (Mw/Mn) of 2.0 or less.

The preferable embodiment 11 according to the present invention is the epoxy resin modifier according to any one of the embodiments 1 to 10, wherein the block copolymer is polymerized by living radical polymerization.

The preferable embodiment 12 according to the present invention is an epoxy resin composition containing an epoxy resin, a curing agent, and the epoxy resin modifier according to any one of the embodiments 1 to 11.

The preferable embodiment 13 according to the present invention is the epoxy resin composition according to the embodiment 12, wherein an amount of the epoxy resin modifier ranges from 1 part by mass to 25 parts by mass in terms of an amount of the A-B-A triblock copolymer with respect to 100 parts by mass of a total amount of the epoxy resin and the curing agent.

The preferable embodiment 14 according to the present invention is an adhesive composed of the epoxy resin composition according to the embodiment 12 or 13.

The preferable embodiment 15 according to the present invention is an underfill material composed of the epoxy resin composition according to the embodiment 12 or 13.

The preferable embodiment 16 according to the present invention is a cured resin product obtained by curing the epoxy resin composition according to the embodiment 12 or 13.

1-16. (canceled)

17. An epoxy resin modifier containing a block copolymer, wherein
the block copolymer is an A-B-A triblock copolymer having an A block that has a structural unit (a-1) represented by the general formula (1) and a structural unit (a-2) derived from a (meth)acrylate having a chain alkyl group, and a B block that has a structural unit (b) derived from at least one vinyl monomer selected from the group consisting of a (meth)acrylate having a chain alkyl group and a (meth)acrylate having a cyclic alkyl group, and
in each of the A blocks, an amount of the structural unit (a-1) represented by the general formula (1) is 85 mass % or more and less than 100 mass % in 100 mass % of the A block, and an amount of the structural unit (a-2) derived from the (meth)acrylate having the chain alkyl group is more than 0 mass % and 15 mass % or less in 100 mass % of the A block, 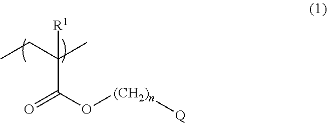
in the general formula (1), R¹ is a hydrogen atom or a methyl group, 0≤n≤10, and Q is a four-membered to six-membered cyclic ether group or cyclic thioether group.

18. The epoxy resin modifier according to claim 17, wherein the structural unit (a-2) of the A block is a structural unit derived from a (meth)acrylate having a branched chain alkyl group.

19. The epoxy resin modifier according to claim 17, wherein the structural unit (a-1) of the A block is a structural unit derived from at least one member selected from the group consisting of tetrahydrofurfuryl (meth)acrylate, morpholino (meth)acrylate, morpholinoethyl (meth)acrylate, (3-ethyloxetan-3-yl)methyl (meth)acrylate, (2-methyl-2-ethyl-1,3-dioxolan-4-yl)methyl (meth)acrylate, cyclic trimethylolpropane formal (meth)acrylate, 2-[(2-tetrahydropyranyl)oxy]ethyl (meth)acrylate, and 1,3-dioxane-(meth)acrylate.

20. The epoxy resin modifier according to claim 17, wherein when the A block having a high amount of the structural unit (a-1) is referred to as A1 block and the A block having a low amount of the structural unit (a-1) is referred to as A2 block of the two A blocks constituting the block copolymer, a mass ratio (A1 block/A2 block) of the A1 block to the A2 block ranges from 0.8 to 1.2.

21. The epoxy resin modifier according to claim 17, wherein an amount of the A block ranges from 30 mass % to 70 mass % in 100 mass % of the entire block copolymer.

22. The epoxy resin modifier according to claim 17, wherein the structural unit (b) of the B block is a structural unit derived from a (meth)acrylate having a chain alkyl group with 11 to 20 carbon atoms.

23. The epoxy resin modifier according to claim 17, wherein an amount of the structural unit (b) of the B block is 80 mass % or more and 100 mass % or less in 100 mass % of the B block.

24. The epoxy resin modifier according to claim 17, wherein an amount of the B block ranges from 30 mass % to 70 mass % in 100 mass % of the entire block copolymer.

25. The epoxy resin modifier according to claim 17, wherein the block copolymer has a weight average molecular weight (Mw) of 10,000 or more and less than 200,000.

26. The epoxy resin modifier according to claim 17, wherein the block copolymer has a molecular weight distribution (Mw/Mn) of 2.0 or less.

27. The epoxy resin modifier according to claim 17, wherein the block copolymer is polymerized by living radical polymerization.

28. An epoxy resin composition comprising an epoxy resin, a curing agent, and an epoxy resin modifier containing a block copolymer,
wherein the block copolymer is an A-B-A triblock copolymer having an A block that has a structural unit (a-1) represented by the general formula (1) and a structural unit (a-2) derived from a (meth)acrylate having a chain alkyl group, and a B block that has a structural unit (b) derived from at least one vinyl monomer selected from the group consisting of a (meth)acrylate having a chain alkyl group and a (meth)acrylate having a cyclic alkyl group, and
in each of the A blocks, an amount of the structural unit (a-1) represented by the general formula (1) is 85 mass % or more and less than 100 mass % in 100 mass % of the A block, and an amount of the structural unit (a-2) derived from the (meth)acrylate having the chain alkyl group is more than 0 mass % and 15 mass % or less in 100 mass % of the A block, 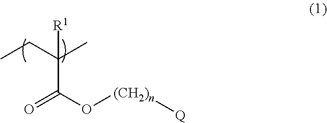
in the general formula (1), R¹ is a hydrogen atom or a methyl group, 0≤n≤10, and Q is a four-membered to six-membered cyclic ether group or cyclic thioether group.

29. The epoxy resin composition according to claim 28, wherein an amount of the epoxy resin modifier ranges from 1 part by mass to 25 parts by mass in terms of an amount of the A-B-A triblock copolymer with respect to 100 parts by mass of a total amount of the epoxy resin and the curing agent.

30. The epoxy resin composition according to claim 28, wherein
the structural unit (a-1) of the A block is a structural unit derived from at least one member selected from the group consisting of tetrahydrofurfuryl (meth)acrylate, morpholino (meth)acrylate, morpholinoethyl (meth)acrylate, (3-ethyloxetan-3-yl)methyl (meth)acrylate, (2-methyl-2-ethyl-1,3-dioxolan-4-yl)methyl (meth)acrylate, cyclic trimethylolpropane formal (meth)acrylate, 2-[(2-tetrahydropyranyl)oxy]ethyl (meth)acrylate, and 1,3-dioxane-(meth)acrylate, and
the structural unit (a-2) of the A block is a structural unit derived from a (meth)acrylate having a branched chain alkyl group.

31. The epoxy resin composition according to claim 30, wherein the structural unit (b) of the B block is a structural unit derived from a (meth)acrylate having a chain alkyl group with 11 to 20 carbon atoms.

32. The epoxy resin composition according to claim 31, wherein an amount of the structural unit (b) of the B block is 80 mass % or more and 100 mass % or less in 100 mass % of the B block.

33. The epoxy resin composition according to claim 32, wherein an amount of the B block ranges from 30 mass % to 70 mass % in 100 mass % of the entire block copolymer.

34. The epoxy resin composition according to claim 28, wherein the block copolymer has a weight average molecular weight (Mw) of 10,000 or more and less than 200,000, and a molecular weight distribution (Mw/Mn) of 2.0 or less.

35. An adhesive composed of the epoxy resin composition according to claim 28.

36. An underfill material composed of the epoxy resin composition according to claim 28.
